(19) United States
(12) Patent Application Publication
(10) Pub. No.: US 2024/0222580 A1
(43) Pub. Date: Jul. 4, 2024

(54) LIGHT-EMITTING SUBSTRATE, DISPLAY APPARATUS AND TILED DISPLAY APPARATUS

(71) Applicant: BOE TECHNOLOGY GROUP CO., LTD., Beijing (CN)

(72) Inventors: Yang YUE, Beijing (CN); Wei WANG, Beijing (CN); Ruoyu MA, Beijing (CN); Shi SHU, Beijing (CN); Yong YU, Beijing (CN); Xiang LI, Beijing (CN); Shaohui LI, Beijing (CN); Qi YAO, Beijing (CN); Shipei LI, Beijing (CN); Renquan GU, Beijing (CN); Wenqu LIU, Beijing (CN); Chuanxiang XU, Beijing (CN)

(21) Appl. No.: 18/262,404

(22) PCT Filed: Jun. 10, 2022
(86) PCT No.: PCT/CN2022/098121

§ 371 Date: Jul. 21, 2023

(51) Int. Cl. H01L 33/62; H01L 25/075

(52) U.S. Cl. CPC H01L 33/62; H01L 25/0753

(57) ABSTRACT

A light-emitting substrate includes a substrate, a first metal layer, a first insulating layer, a second metal layer and a conductive adhesive. A bonding region is proximate to a selected side edge of a first surface of the substrate. The first metal layer on the first surface includes first bonding electrodes. The first insulating layer is on the first metal layer, and a border thereof proximate to the edge is closer to the edge than a border of the first bonding electrodes facing the edge. The second metal layer includes second bonding electrodes. The conductive adhesive in the bonding region covers portions of the second bonding electrodes. A ratio of a dimension of an edge portion of the first insulating layer in a second direction to a dimension of a first bonding electrode in same direction is greater than or equal to ⅕ and less than or equal to ½.

### CROSS-REFERENCE TO RELATED APPLICATION

This application is a national phase entry under 35 USC 371 of International Patent Application No. PCT/CN2022/098121 filed on Jun. 10, 2022, which is incorporated herein by reference in its entirety.

### TECHNICAL FIELD

The present disclosure relates to the field of display technology, and in particular, to a light-emitting substrate, a display apparatus and a tiled display apparatus.

### BACKGROUND

Mini-LED (Mini Light-Emitting Diode), also known as “sub-millimeter light-emitting diode”, refers to an LED having a grain size of about 100 μm or less, and Mini-LED display apparatuses have the characteristics of strong luminance, high resolution and the like. The Mini-LED is currently driven by using Mini-IC (Mini Integrated Circuit).

### SUMMARY

In an aspect, a light-emitting substrate is provided. The light-emitting substrate has a display region and a bonding region disposed on a side of the display region. The bonding region extends along a first direction. The light-emitting substrate includes: a substrate, a first metal layer disposed on a side of a first surface of the substrate, a first insulating layer disposed on a side of the first metal layer away from the substrate, a second metal layer disposed on a side of the first insulating layer away from the first metal layer, and a conductive adhesive located in the bonding region. The first surface of the substrate includes a selected side edge, and the bonding region is proximate to the selected side edge. The first metal layer includes a plurality of first bonding electrodes spaced apart along the first direction, and portions of the plurality of first bonding electrodes proximate to the selected side edge are located in the bonding region. The first insulating layer includes a plurality of via holes penetrating to the first metal layer, and a border of the first insulating layer proximate to the selected side edge is closer to the selected side edge than a border of the plurality of first bonding electrodes facing the selected side edge. The second metal layer includes a plurality of second bonding electrodes, each second bonding electrode is connected to a corresponding first bonding electrode through a via hole. The conductive adhesive covers portions of the plurality of second bonding electrodes proximate to the selected side edge. A ratio of a dimension of an edge portion of the first insulating layer in a second direction to a dimension of a first bonding electrode in the second direction is greater than or equal to one fifth (⅕) and less than or equal to a half (½), the edge portion of the first insulating layer is a portion, located between the border of the plurality of first bonding electrodes facing the selected side edge and the selected side edge, of the first insulating layer, and the second direction is perpendicular to the first direction.

In some embodiments, a distance between the border of the first insulating layer proximate to the selected side edge and the selected side edge is less than a distance between an end of the conductive adhesive proximate to the selected side edge and the selected side edge.

In some embodiments, the ratio of the dimension of the edge portion of the first insulating layer in the second direction to the dimension of the first bonding electrode in the second direction is greater than or equal to one third (⅓) and less than or equal to a half (½).

In some embodiments, the light-emitting substrate further includes an insulating barrier layer disposed on a side of the second metal layer away from the substrate. The insulating barrier layer includes an edge portion located in the bonding region. The edge portion of the insulating barrier layer is at least disposed on a side of the edge portion of the first insulating layer away from the substrate. A border of the insulating barrier layer proximate to the selected side edge is closer to the selected side edge than the border of the first insulating layer proximate to the selected side edge.

In some embodiments, the light-emitting substrate has the display region and a peripheral region outside the display region, and the plurality of first bonding electrodes and the plurality of second bonding electrodes are located in the peripheral region. The peripheral region includes the bonding region. The light-emitting substrate further includes a first passivation layer disposed on a side of the second metal layer away from the substrate. The first passivation layer includes an edge portion located in the bonding region, and the edge portion of the first passivation layer serves as the edge portion of the insulating barrier layer.

In some embodiments, the light-emitting substrate has the display region and a peripheral region outside the display region, and the plurality of first bonding electrodes and the plurality of second bonding electrodes are located in the peripheral region. The peripheral region includes the bonding region. The light-emitting substrate further includes a first passivation layer disposed on a side of the second metal layer away from the substrate, and a second insulating layer disposed on a side of the first passivation layer away from the substrate. The first passivation layer includes a first portion located in the peripheral region, and the first portion of the first passivation layer is located on a side, away from the substrate, of portions of the plurality of second bonding electrodes proximate to the display region. The second insulating layer includes an edge portion located in the bonding region, and the edge portion of the second passivation layer serves as the edge portion of the insulating barrier layer.

In some embodiments, the edge portion of the second insulating layer extends to the selected side edge.

In some embodiments, the second metal layer further includes residual metal located in the bonding region, the residual metal is located at a border of the first insulating layer proximate to the selected side edge, and the residual metal extends in the first direction. The conductive adhesive is electrically insulated from the residual metal.

In some embodiments, the display region includes display unit regions, and a display unit region includes a light-emitting zone and a driving zone. The first metal layer further includes a plurality of first signal lines located in the display region, at least one first signal line passes through the light-emitting zone, and the plurality of first signal lines do not pass through the driving zone. The light-emitting substrate further includes: light-emitting device groups disposed in light-emitting zones, driving chips disposed in driving zones, and at least one prop structure disposed in the driving zones. A light-emitting device group is located on a side of the second metal layer away from the substrate and electrically connected to the second metal layer, and an orthographic projection of the light-emitting device group on the substrate is within an orthographic projection of a portion of the at least one first signal line passing through the light-emitting zone on the substrate. A driving chip is electrically connected to both the second metal layer and the light-emitting device group. The at least one prop structure is located between the driving chip and the substrate, and a prop structure is configured to increase a distance between the driving chip and the substrate.

In some embodiments, the first metal layer further includes: pads, wherein a pad is located in the driving zone and serves as the prop structure, and the pad is electrically insulated from the plurality of first signal lines and electrically insulated from the second metal layer. An orthographic projection of the driving chip on the substrate is within an orthographic projection of the pad on the substrate.

In some embodiments, the light-emitting substrate further includes a third insulating layer, the third insulating layer includes at least one insulating structure, an insulating structure is located in the driving zone and serves as the prop structure, and an orthographic projection of the driving chip on the substrate is within an orthographic projection of the insulating structure on the substrate.

In some embodiments, the third insulating layer is located between the first insulating layer and the second metal layer or between the substrate and the first insulating layer.

In some embodiments, the light-emitting substrate has the display region and a peripheral region outside the display region, the peripheral region includes a cut-off region and the bonding region, and the cut-off region and the bonding region are located at different sides of the display region. The light-emitting substrate further includes a plurality of test connection lines located in the first metal layer, ends of the plurality of test connection lines are located in the display region, and other ends of the plurality of test connection lines extend to the cut-off region and are flush with a border of the cut-off region away from the display region.

In some embodiments, the light-emitting substrate has the display region and a peripheral region outside the display region, the peripheral region includes a cut-off region and the bonding region, and the cut-off region and the bonding region are located at different sides of the display region. The light-emitting substrate further includes a plurality of test connection lines and a protection structure located in the second metal layer, ends of the plurality of test connection lines are located in the display region, other ends of the plurality of test connection lines extend to the cut-off region and are flush with a border of the cut-off region away from the display region; and the protection structure is configured to prevent the plurality of test connection lines from being short-connected.

In some embodiments, the first insulating layer extends to the cut-off region, a border of the first insulating layer proximate to the cut-off region is flush with the border of the cut-off region away from the display region, and a portion of the first insulating layer extending to the cut-off region serves as the protection structure.

In some embodiments, the first insulating layer does not extend to the cut-off region. The light-emitting substrate further includes a plurality of isolation retaining walls located in the cut-off region, and the plurality of isolation retaining walls are made of an insulating material; and each isolation retaining wall is disposed between two adjacent test connection lines, and the isolation retaining walls serve as the protection structure.

In another aspect, a light-emitting substrate is provided. The light-emitting substrate has a display region, the display region includes display unit regions, and a display unit region includes a light-emitting zone and a driving zone. The light-emitting substrate includes: a substrate, a first metal layer disposed on a side of a first surface of the substrate, a first insulating layer disposed on a side of the first metal layer away from the substrate, a second metal layer disposed on a side of the first insulating layer away from the first metal layer, light-emitting device groups located in light-emitting zones, driving chips located in driving zones, and prop structures located in the driving zones. The first metal layer includes a plurality of first signal lines located in the display region, at least one first signal line passes through the light-emitting zone, and the plurality of first signal lines do not pass through the driving zone. The second metal layer includes a plurality of second signal lines located in the display region. A light-emitting device group is disposed on a side of the second metal layer away from the substrate and electrically connected to the second metal layer, and an orthographic projection of the light-emitting device group on the substrate is within an orthographic projection of a portion of the at least one first signal line passing through the light-emitting zone on the substrate. A driving chip is disposed on the side of the second metal layer away from the substrate and electrically connected to both the second metal layer and the light-emitting device group. A prop structures is disposed between the driving chip and the substrate, and configured to increase a distance between the driving chip and the substrate.

In some embodiments, the light-emitting device group includes a plurality of light-emitting devices, and the light-emitting devices are mini light-emitting diodes or micro light-emitting diodes.

In yet another aspect, a light-emitting substrate is provided, the light-emitting substrate includes a display region and a peripheral region outside the display region, and the peripheral region includes a cut-off region.

The light-emitting substrate includes a substrate, a first metal layer disposed on a side of a first surface of the substrate, a first insulating layer disposed on a side of the first metal layer away from the substrate, a second metal layer disposed on a side of the first insulating layer away from the first metal layer, and a protection structure. The second metal layer includes a plurality of test connection lines, ends of the plurality of test connection lines are located in the display region, and other ends of the plurality of test connection lines extends to the cut-off region and are flush with a border of the cut-off region away from the display region. The protection structure is configured to prevent the plurality of test connection lines from being short-connected.

In yet another aspect, a display apparatus is provided, including the light-emitting substrate according to any one of the above embodiments.

In yet another aspect, a tiled display apparatus is provided, including a plurality of display apparatuses each according to any one of the above embodiments.

In some embodiments, the plurality of display apparatuses are arranged in an array along a first direction and a second direction. A light-emitting substrate included in each display apparatus has a display region and a peripheral region outside the display region, the peripheral region includes a cut-off region and a bonding region, and the cut-off region and the bonding region are located at different sides of the display region. A side surface of each display apparatus proximate to a side on which the light-emitting substrate included therein is provided with the bonding region is a first side surface, a side surface of each display apparatus proximate to a side on which the light-emitting substrate included therein is provided with the cut-off region is a second side surface, and the bonding region and the cut-off region of the light-emitting substrate extend along the first direction. First side surfaces of two adjacent display apparatuses are coplanar, and second side surfaces of the two adjacent display apparatuses are coplanar. A size of a seam between two adjacent display apparatuses among multiple display apparatuses arranged in a row along the first direction is less than a size of a seam between two adjacent display apparatuses among multiple display apparatuses arranged in a column along the second direction.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person having ordinary skill in the art can obtain other drawings according to these accompanying drawings. In addition, the accompanying drawings to be described below may be regarded as schematic diagrams, and are not limitations on an actual size of a product, an actual process of a method and an actual timing of a signal involved in the embodiments of the present disclosure.

FIG. 1 is a cross-sectional structural diagram of a light-emitting substrate, in accordance with some embodiments;

FIG. 2 is a structural diagram of a light-emitting substrate, in accordance with some embodiments;

FIG. 3 is an enlarged structural diagram of the region G1 in FIG. 1;

FIG. 4 is a cross-sectional structural diagram of a light-emitting substrate obtained according to the section line DD in FIG. 3, in accordance with some embodiments;

FIG. 5 is a cross-sectional structural diagram of a light-emitting substrate obtained according to the section line DD in FIG. 3, in accordance with some embodiments;

FIG. 6 is a cross-sectional structural diagram of a light-emitting substrate obtained according to the section line DD in FIG. 3, in accordance with some other embodiments;

FIG. 7 is a cross-sectional structural diagram of a light-emitting substrate obtained according to the section line DD in FIG. 3, in accordance with yet some other embodiments;

FIG. 8A is a structural diagram of a display unit region of a light-emitting substrate, in accordance with some embodiments;

FIG. 8B is an enlarged structural diagram of the region G2 in FIG. 1;

FIG. 9 is a cross-sectional structural diagram of a light-emitting substrate obtained according to the section line EE in FIG. 8B, in accordance with some embodiments;

FIG. 10 is a cross-sectional structural diagram of a light-emitting substrate obtained according to the section line EE in FIG. 8B, in accordance with some embodiments;

FIG. 11 is a cross-sectional structural diagram of a light-emitting substrate obtained according to the section line EE in FIG. 8B, in accordance with some other embodiments;

FIG. 12 is a structural diagram of a light-emitting substrate before a test region is cut off, in accordance with some embodiments;

FIG. 13 is a cross-sectional structural diagram of a light-emitting substrate obtained according to the section line HH in FIG. 12, in accordance with some embodiments of the related art;

FIG. 14 is a cross-sectional structural diagram of a light-emitting substrate obtained according to the section line HH in FIG. 12, in accordance with some other embodiments;

FIG. 15 is an enlarged structural diagram of the region F in FIG. 12;

FIG. 16 is a cross-sectional structural diagram of a light-emitting substrate obtained according to the section line HH in FIG. 12, in accordance with yet some other embodiments;

FIG. 17 is a structural diagram of a display apparatus, in accordance with some embodiments; and

FIG. 18 is a structural diagram of a tiled display apparatus, in accordance with some embodiments.

### DETAILED DESCRIPTION

Technical solutions in some embodiments of the present disclosure will be described clearly and completely with reference to the accompanying drawings below. Obviously, the described embodiments are merely some but not all embodiments of the present disclosure. All other embodiments obtained by a person having ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed in an open and inclusive meaning, i.e., “including, but not limited to”. In the description of the specification, the terms such as “one embodiment,” “some embodiments,” “exemplary embodiments,” “example.” “specific example” or “some examples” are intended to indicate that specific features, structures, materials or characteristics related to the embodiment(s) or example(s) are included in at least one embodiment or example of the present disclosure. Schematic representations of the above term do not necessarily refer to the same embodiment(s) or example(s). In addition, specific features, structures, materials or characteristics may be included in any one or more embodiments or examples in any suitable manner.

Hereinafter, the terms such as “first” and “second” are used for descriptive purposes only, but are not to be construed as indicating or implying the relative importance or implicitly indicating the number of indicated technical features. Thus, the features defined with “first” and “second” may explicitly or implicitly include one or more of the features. In the description of the embodiments of the present disclosure, the term “a (the) plurality of/multiple” mean two or more unless otherwise specified.

“A and/or B” includes following three combinations: only A, only B, and a combination of A and B.

The use of “adapted to” or “configured to” herein means an open and inclusive language, which does not exclude apparatuses that are applicable to or configured to perform additional tasks or steps.

In addition, the use of “based on” means open and inclusive, as the process, step, calculation, or other action “based on” one or more of the stated conditions or values may in practice be based on additional conditions or beyond the recited values.

The term such as “about”, “substantially” or “approximately” as used herein includes a stated value and an average value within an acceptable range of deviation of a particular value determined by a person of ordinary skill in the art, considering measurement in question and errors associated with measurement of a particular quantity (i.e., limitations of a measurement system).

It will be understood that, when a layer or element is referred to as being on another layer or substrate, it may be that the layer or element is directly on the another layer or substrate, or that there is an intermediate layer between the layer or element and the another layer or substrate.

Exemplary embodiments are described herein with reference to segmental views and/or plan views as idealized exemplary drawings. In the accompanying drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a feature of being curved. Therefore, the regions shown in the accompanying drawings are schematic in nature, and their shapes are not intended to show actual shapes of regions in an apparatus, and are not intended to limit the scope of the exemplary embodiments.

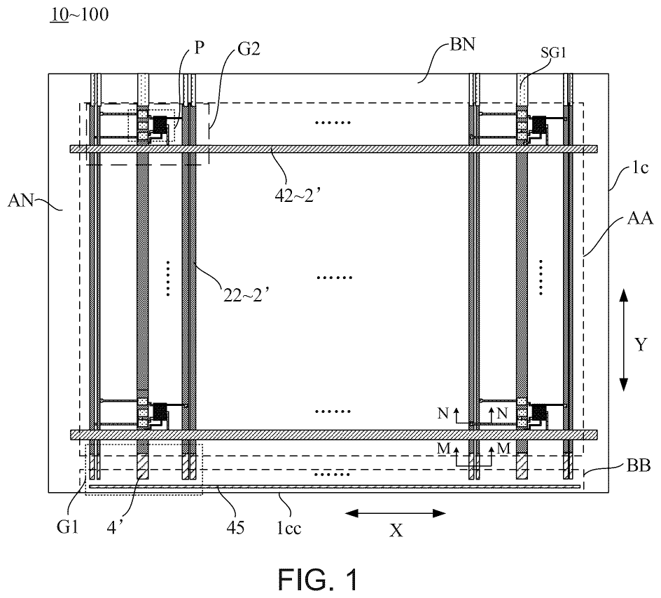

Some embodiments of the present disclosure provide a light-emitting substrate 10. As shown in FIG. 1, the light-emitting substrate 10 has a display region AA and a peripheral region AN disposed on at least one side of the display region AA, for example, the peripheral region AN is disposed around the display region AA. The display region AA is provided with a plurality of pixels and a plurality of signal lines 2′, and the peripheral region AN is provided with a plurality of bonding electrodes 4′ for connecting an external driver chip and structures in the display region AA. The peripheral region AN includes a bonding region BB, for example, the bonding region BB is located on a side of the display region AA, and the bonding region BB is proximate to a side edge of the light-emitting substrate 10 and extends along the first direction X.

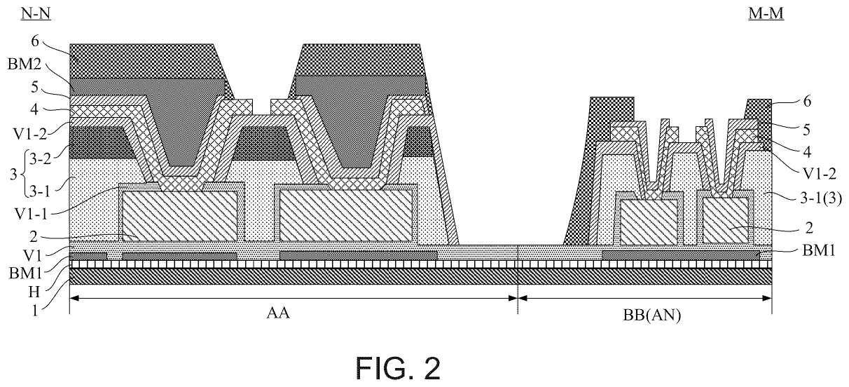

The following will describe structures of film layers included in the light-emitting substrate. As shown in FIG. 2, the light-emitting substrate 10 includes: a substrate 1, a buffer layer H, a first light shielding layer BM1, a second passivation layer V1, a first metal layer 2, a third passivation layer V1-1, a first insulating layer 3, a fourth passivation layer V1-2, a second metal layer 4, a first passivation layer 5, a second light shielding layer BM2, and a second insulating layer 6, which are disposed in sequence. The light-emitting substrate further includes a plurality of light-emitting devices, driving chips, and the like, which will described in detail in the subsequent content and are not described here. The buffer layer H is disposed on a side of a first surface 1a of the substrate 1. The first surface 1a of the substrate 1 includes a plurality of side edges 1c, one of the side edges is a selected side edge 1cc, and the bonding region BB is proximate to the selected side edge 1cc.

It will be noted that, in order to compare and illustrate patterns of film layers of the display region AA and patterns of film layers of the peripheral region AN, sectional views obtained along the section line N-N and the section line M-M in FIG. 1 are combined to obtain the sectional view shown in FIG. 2. In the display region AA, the first metal layer 2 includes a plurality of first signal lines 22, for example, the plurality of first signal lines 22 extend along the second direction Y; and the second metal layer 4 includes a plurality of second signal lines 42 and a plurality of bonding pads, for example, the plurality of second signal lines 42 extend along the first direction X. In the peripheral region AN, the first metal layer 2 includes a plurality of first bonding electrodes 21, the plurality of first bonding electrodes 21 are spaced apart along the first direction X, and portions of the plurality of first bonding electrodes 21 proximate to the selected side edge 1cc are located in the bonding region BB; and the second metal layer 4 includes a plurality of second bonding electrodes 41, the plurality of second bonding electrodes 41 are spaced apart along the first direction X, and portions of the plurality of second bonding electrodes 41 proximate to the selected side edge 1cc are located in the bonding region BB. Each bonding electrodes 4′ includes a first bonding electrode 21 and a second bonding electrode 41, positions of the first bonding electrode 21 and the second bonding electrode 41 correspond to each other, that is, orthographic projections of the first bonding electrode 21 and the second bonding electrode 41 included in each bonding electrodes 4′ on the substrate 1 overlaps or substantially overlaps. The third passivation layer V1-1, the first insulating layer 3, and the fourth passivation layer V1-2 that are between the first metal layer 2 and the second metal layer 4 are provided therein with a plurality of via holes penetrating through the first metal layer 2, and the first bonding electrode 21 and second bonding electrode 41 corresponding to each other are electrically connected through a via hole.

In some examples, only the first bonding electrode 21 is provided as the bonding electrode 4′, and the first bonding electrode 21 is located in the first metal layer 2. A side of the first metal layer 2 away from the substrate 1 is further provided thereon with a plurality of film layer structures, and a bonding process, i.e., bonding and attaching the bonding electrode 4′ and a flexible circuit board 7′, is performed after preparations of all the film layers on the substrate 1 are completed. It can be understood that in a manufacturing process of the light-emitting substrate 10, a preparation process of the first metal layer 2 is before the bonding process. The first bonding electrode 21 needs to be connected to the flexible circuit board 7′, so that a plurality of film layers on a side of the first bonding electrode 21 away from the substrate 1 all expose the first bonding electrode 21. That is, after the first metal layer 2 is prepared and before the bonding process is performed, the first bonding electrode 21 in the first metal layer 2 is always exposed. As a result, the exposed first bonding electrode 21 is in contact with air and moisture in air, so that the first bonding electrode 21 is easily corroded by water and oxygen. In the subsequent bonding process, when the flexible circuit board 7′ is attached, a connection between the flexible circuit board 7′ and the first bonding electrode 21 is poor, so that a loss rate of a signal transmission between the flexible circuit board 7′ and the first bonding electrode 21 is high, which cannot ensure a stable and effective signal transmission between the flexible circuit board 7′ and the first bonding electrode 21, and affects normal operation of the light-emitting substrate 10.

The bonding process is a process in which the flexible circuit board 7′ is attached to a side of the bonding electrode 4′ away from the substrate 1, thereby realizing an electrical connection between the bonding electrode 4′ and the flexible circuit board 7′. The bonding defect refers to that the bonding electrode 4′ is corroded by water and oxygen, so that when the flexible circuit board 7′ is bonded, the connection between the bonding electrode 4′ and the flexible circuit board 7′ is poor, which cannot meet the design requirements.

In other examples, only the second bonding electrode 41 is provided as the bonding electrode 4′. The second bonding electrode 41 is located in the second metal layer 4, and a thickness of the second metal layer 4 is less than a thickness of the first metal layer 2. As a result, only the second bonding electrode 41 provided as the bonding electrode 4′ is bonded to the flexible circuit board 7′, and because the thickness of the second bonding electrode 41 is small, it is difficult to meet electrical requirements required by the bonding electrode 4′, so that a loss rate of a signal transmission between the flexible circuit board 7′ and the second bonding electrode 41 is high, which cannot ensure a stable and effective signal transmission between the flexible circuit board 7′ and the second bonding electrode 41, and affects normal operation of the light-emitting substrate 10.

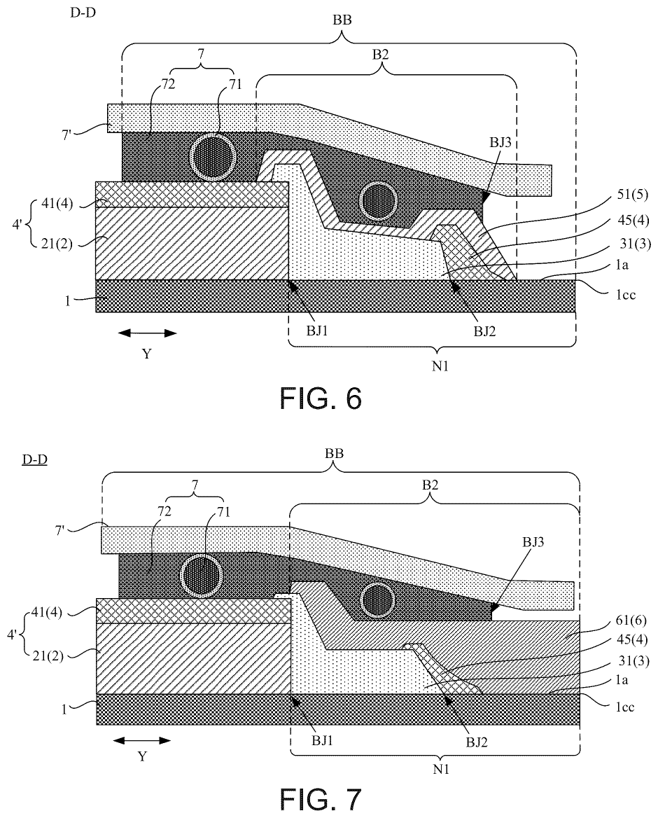

In some embodiments of the present disclosure, as shown in FIG. 5, FIG. 6 and FIG. 7, each bonding electrode 4′ is of a double-layer design, each bonding electrode 4′ includes a first bonding electrode 21 and a second bonding electrode 41, and orthographic projections of the first bonding electrode 21 and the second bonding electrode 41 included in each bonding electrode 4′ on the substrate 1 overlap or substantially overlap, and the first bonding electrode 21 and the second bonding electrode 41 included in each bonding electrode 4′ are electrically connected. It can be understood that, during the manufacturing process of the light-emitting substrate 10, when the second metal layer 4 is prepared, the second bonding electrode 41 in the second metal layer 4 covers the first bonding electrode 21 at a side of the second metal layer 4 away from the substrate 1, thereby reducing time that the first bonding electrode 21 is exposed before the bonding process. By designing the bonding electrode 4′ using a double-metal layer, a thickness of the bonding electrode 4′ is increased compared with a case in which only the first bonding electrode 21 or the second bonding electrode 41 serves as the bonding electrode 4′. That is, a dimension of the bonding electrode 4′ in a direction perpendicular to the substrate 1 is increased, a resistance of the bonding electrode 4′ may be effectively reduced, thereby reducing a loss rate of a signal transmission between the flexible circuit board 7′ and the bonding electrode 4′, and ensuring a stable and effective signal transmission between the flexible circuit board 7′ and the bonding electrode 4′.

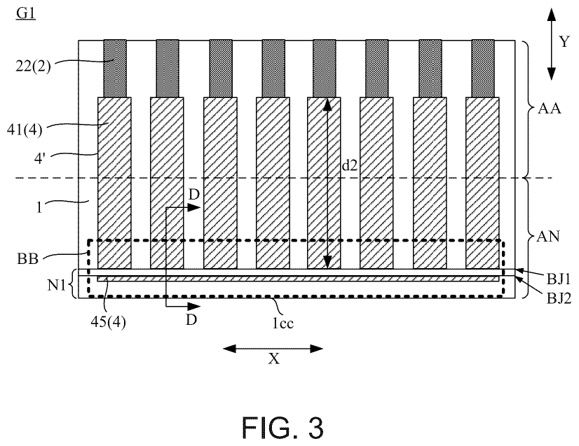

For example, as shown in FIG. 3, a first signal line 22 is electrically connected to a first bonding electrode 41, so as to be electrically connected to a bonding electrode 4′. The external driver chip transmits driving signals to the plurality of bonding electrodes 4′, and then the plurality of bonding electrodes 4′ transmit the driving signals to the plurality of first signal lines 22. The external driver chip is electrically connected to the plurality of bonding electrodes 4′ through the flexible circuit board 7′. In some embodiments, as shown in FIG. 5, FIG. 6 and FIG. 7, a conductive adhesive 7 is disposed in the bonding region BB, the conductive adhesive 7 is located between the flexible circuit board 7′ and the plurality of bonding electrodes 4′, and the conductive adhesive 7 covers portions of the plurality of second bonding electrodes 41 proximate to the selected side edge 1cc. The conductive adhesive 7 is configured to bond the flexible circuit board 7′ to realize an electrical connection between the plurality of second bonding electrodes 41 and the flexible circuit board 7′.

In some embodiments, as shown in FIG. 2, a material of the passivation layers, e.g., the second passivation layer V1, the third passivation layer V1-1, the fourth passivation layer V1-2, and the first passivation layer 5, is an inorganic material, such as silicon nitride. In embodiments of the present disclosure, a material of the insulating layers, e.g., the first insulating layer 3 and the second insulating layer 6, is an organic material, for example, the first insulating layer 3 and the second insulating layer 6 are OC (Over Coating) adhesive layers. In some examples, each of the passivation layers and the insulating layers covers the display region AA and a portion of the peripheral region AN, that is, a border of each passivation layer or insulating layer extends to the peripheral region AN.

For example, as shown in FIG. 2, the first insulating layer 3 includes a first insulating sub-layer 3-1 and a second insulating sub-layer 3-2, and the first insulating sub-layer 3-1 is closer to the substrate 1 than the second insulating sub-layer 3-2. Both the first insulating sub-layer 3-1 and the second insulating sub-layer 3-2 are disposed in the display region AA and the peripheral region AN.

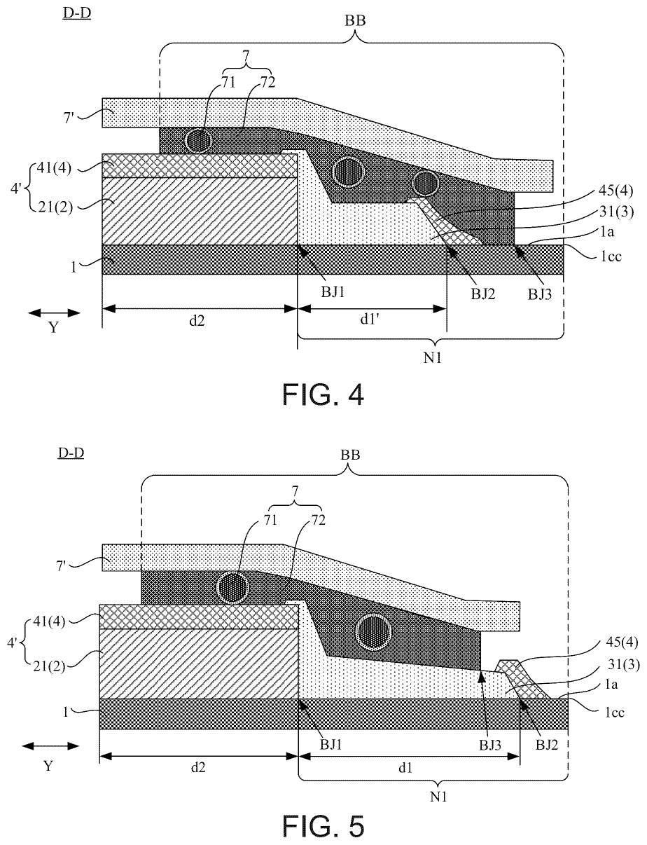

In some examples, as shown in FIG. 3 and FIG. 4, borders of the first insulating layer 3 extend into the bonding region BB, and a border BJ2 of the first insulating layer 3 proximate to the selected side edge 1cc of the substrate 1 is closer to the selected side edge 1cc than a border BJ1 of the plurality of first bonding electrodes 21 facing the selected side edge. A region between the border BJ1 of the plurality of first bonding electrodes 21 facing the selected side and the selected side 1cc is referred to as a side edge region N1 hereinafter. It can be understood that, in FIG. 3, since the second bonding electrode 41 is located on a side of the first bonding electrode 21 away from the substrate 1, the plurality of first bonding electrodes 21 cannot be illustrated in FIG. 3, and it can be considered that the border BJ1 of the plurality of first bonding electrodes 21 facing the selected side edge 1cc and a border BJ1 of the plurality of second bonding electrodes 41 facing the selected side edge 1cc are a same border. In addition, as shown in FIG. 4, borders of the first passivation layer 5 and the second insulating layer 6 do not extend to the side edge region N1, so the borders of the first passivation layer 5 and the second insulating layer 6 do not extend beyond the border BJ1 of the plurality of first bonding electrodes 21 facing the selected side edge 1cc.

In addition, as shown in FIG. 3 and FIG. 4, the border BJ2 of the first insulating layer 3 proximate to the selected side edge 1cc of the substrate 1 is located in the bonding region BB. A portion, located between the border BJ1 of the plurality of first bonding electrodes 21 facing the selected side edge 1cc and the selected side edge 1cc (that is, a portion located in the side edge region N1), of the first insulating layer 3 is referred to as an edge portion 31 of the first insulating layer 3 hereinafter. In this way, when the conductive adhesive 7 is attached, the conductive adhesive 7 is in direct contact with at least the portions of the plurality of second bonding electrodes 41 proximate to the selected side edge 1cc of the light-emitting substrate 10, and the conductive adhesive 7 is further in contact with an uppermost film layer (a film layer farthest from the substrate 1) in the other film layers located in the bonding region BB, for example, the conductive adhesive 7 is further in contact with a surface of the edge portion 31 of the first insulating layer 3 and the border BJ2. The conductive adhesive 7 is a long conductive adhesive strip disposed in the bonding region BB. The flexible circuit board 7′ includes a plurality of conductive contact pieces, and each of the conductive contact pieces corresponds to a bonding electrode. Each second bonding electrode is electrically connected to a conductive contact piece corresponding thereto through the conductive adhesive, thereby realizing the bonding of the flexible circuit board and the plurality of bonding electrodes.

As shown in FIG. 4, when the flexible circuit board 7′ is bonded, firstly, the conductive adhesive 7 is attached to a side of the plurality of second bonding electrodes 41 away from the substrate 1, and the conductive adhesive 7 is disposed in the bonding region BB. The conductive adhesive 7 is, for example, an anisotropic conductive film (ACF). The conductive adhesive 7 includes an adhesive 72 and a plurality of conductive particles 71, where the plurality of conductive particles 71 are distributed in the adhesive 72. Next, pressure is applied to the flexible circuit board 7′ from a side of the flexible circuit board 7′ away from the ACF to perform an attachment of the flexible circuit board 7. When the pressure is applied to the flexible circuit board 7′, in a direction perpendicular to the substrate 1 and in regions corresponding to the plurality of second bonding electrodes 41, the conductive particles 71 in the ACF are pressed to be conductive, a second bonding electrode 41 and a conductive contact piece corresponding to each other are electrically connected. In this way, the plurality of second bonding electrodes 41 are electrically connected to the flexible circuit board 7′ separately through the plurality of conductive particles 71 in the ACF. The ACF can be conductive in the vertical direction and insulated in the horizontal direction. That is, the ACF is only conductive in a direction in which the plurality of second bonding electrodes 41 are connected to the flexible circuit board 7′, so that the plurality of second bonding electrodes 41 are electrically connected to the flexible circuit board 7′ separately, and in the horizontal direction in which the plurality of second bonding electrodes 41 are arranged, the plurality of second bonding electrodes 41 are not electrically connected through ACF.

In some cases, a preparation method of the first metal layer 2 and the second metal layer 4 includes, for example, firstly, forming a conductive film layer by an electroplating process or a sputtering process, where the conductive film layer adopts a metal material with good electrical conductivity, such as copper; then, etching the conductive film layer by a photolithography process, thereby forming a conductive pattern in the conductive film layer. For the first metal layer 2, the conductive pattern refers to the plurality of first bonding electrodes 21 and the plurality of first signal lines 22 included in the first metal layer 2; for the second metal layer 4, the conductive pattern refers to the plurality of second bonding electrodes 41 and the plurality of second signal lines 42 included in the second metal layer 4.

The electroplating process, the sputtering process, and the photolithography process described above are only examples of the process used in the preparation method, and are not limited by the process in the actual preparation process.

In the preparation process of the second metal layer 4, in addition to forming the plurality of second signal lines 42 and the plurality of second bonding electrodes 41 by etching, since there is a height difference at the border BJ2 of the first insulating layer 3, when the second metal layer 4 is prepared, a portion of the conductive film layer for preparing the second metal layer 4 that should be removed by the photolithography process is easily left at the border BJ2 of the first insulating layer 3, that is, the second metal layer 4 further includes a residual metal 45 located in the peripheral region AN, and the residual metal 45 is located at the border BJ2 of the first insulating layer 3 proximate to the selected side edge 1cc. The residual metal 45 extends along the first direction X, and in a microscope image of the light-emitting substrate 10, the residual metal 45 appears as a bright line, that is, the residual metal 45 is a strip-shaped continuous pattern extending along the first direction X. It can be understood that the residual metal 45 at the border of the edge portion 31 of the first insulating layer 3 proximate to the selected side edge 1cc is the residual metal 45 generated during the production and preparation of the second metal layer 4, which is a portion that needs to be removed by processes or avoided by other design, rather than a portion that needs to be reserved in the product design.

As shown in FIG. 4, the conductive adhesive 7 is in contact with the surface of the edge portion 31 of the first insulating layer 3 and the border BJ2. In a case that the residual metal 45 exists, the conductive adhesive 7 will be further in contact with the residual metal 45, that is, there are at least the portions of the plurality of second bonding electrodes 41 in an attachment region of the conductive adhesive 7, and there are further the residual metal 45. Then the plurality of second bonding electrodes 41 will form a loop through the conductive adhesive 7 and the residual metal 45, which causes the plurality of second bonding electrodes 41 to be short-connected, thereby causing the driving signal provided by the external driver chip not to be transmitted normally to the display region AA, and further affecting the normal operation of the light-emitting substrate 10, for example, a large region of uncontrollable lines appears, which appears as a blurry screen. Here, the short-connected refers to that at least two second bonding electrodes of the plurality of second bonding electrodes 41 are electrically connected through the conductive adhesive 7 and the residual metal 45, so that the at least two second bonding electrodes 41 electrically connected by the conductive adhesive 7 and the residual metal 45 form a loop, causing a short-circuit.

In light of this, some embodiments of the present disclosure provide some structural design on the peripheral region to solve the problem of short-connection of bonding electrodes.

In some embodiments, as shown in FIG. 5, a ratio of a dimension d1 of the edge portion 31 of the first insulating layer 3 in the second direction Y to a dimension d2 of the first bonding electrode 21 in the second direction Y is greater than or equal to one fifth (⅕) and less than or equal to a half (½), where the second direction Y is perpendicular to the first direction X. For example, the ratio of d1 to d2 is ⅕, or ⅓, or ½.

As shown in FIG. 5, by increasing the ratio of the dimension d1 of the edge portion 31 of the first insulating layer 3 in the second direction Y to the dimension d2 of the first bonding electrode 21 in the second direction Y, i.e., increasing the d1/d2, in a case that the dimension d2 of the first bonding electrode 21 in the second direction Y is a constant value, it is equivalent to increasing the dimension d1 of the edge portion 31 of the first insulating layer 3 in the second direction Y. That is, in some embodiments of the present disclosure, compared with a dimension d1′ of the edge portion 31 of the first insulating layer 3 in the second direction Y as shown in FIG. 4, the dimension d1 of the edge portion 31 of the first insulating layer 3 in the second direction Y is increased, so that the border of the edge portion 31 of the first insulating layer 3 extends a position closer to the selected side edge of the substrate 1. As a result, a slope of a bevel edge of a cross-sectional shape of the edge portion 31 of the first insulating layer 3 is reduced, that is, the bevel edge is more gradual. In this way, the height difference between the border BJ2 of the first insulating layer 3 proximate to the selected side edge 1cc and a portion of the first insulating layer 3 proximate to the second bonding electrode 41 may be effectively reduced, and therefore, the probability that the residual metal 45 is generated at the first insulating layer 3 proximate to the selected side edge 1cc may be effectively reduced in the preparation process of the second metal layer 4, thereby reducing the probability of short-connection of the bonding electrodes. Moreover, even if the residual metal 45 is still generated, because d1/d2 is increased, the dimension d1 of the edge portion 31 of the first insulating layer 3 in the second direction Y is increased, compared with FIG. 4 and FIG. 5, the border BJ2 of the edge portion 31 of the first insulating layer 3 as shown in FIG. 5 is closer to the selected side edge 1cc, the border BJ2 of the edge portion 31 of the first insulating layer 3 exceeds a border BJ3 of an end of the conductive adhesive 7 proximate to the selected side edge, and there is a certain distance therebetween, so that the conductive adhesive 7 located in the bonding region BB does not contact the residual metal 45, thereby avoiding the problem that the plurality of bonding electrodes are short-connected through the conductive adhesive 7 and the residual metal 45.

In some examples, as shown in FIG. 5, a distance between the border BJ2 of the first insulating layer 3 proximate to the selected side edge 1cc and the selected side edge 1cc is less than a distance between the end of the conductive adhesive 7 proximate to the selected side edge 1cc and the selected side edge 1cc. Further, borders of an orthographic projection of the first insulating layer 3 on the substrate 1 surround borders of an orthographic projection of the conductive adhesive 7 on the substrate 1.

The border BJ2 of the first insulating layer 3 proximate to the selected side edge 1cc and the conductive adhesive 7 both extend along the first direction X, and the residual metal 45 also extends along the first direction X. Of two ends of the conductive adhesive 7 arranged along a direction perpendicular to an extension direction of the conductive adhesive 7, an end closer to the selected side edge 1cc is the end of the conductive adhesive 7 proximate to the selected side edge 1cc. Since the dimension d1 of the edge portion 31 of the first insulating layer 3 in the second direction Y is increased, the distance between the border BJ2 of the first insulating layer 3 proximate to the selected side edge 1cc and the selected side edge 1cc is less than the distance between the end of the conductive adhesive 7 proximate to the selected side edge 1cc and the selected side edge 1cc. That is to say, compared with the conductive adhesive 7, the border BJ2 of the first insulating layer 3 proximate to the selected side edge 1cc is closer to the selected side edge 1cc, the residual metal 45 is closer to the selected side edge 1cc than the conductive adhesive 7, and a position of the residual metal 45 is not in a coverage of the conductive adhesive 7, so that the conductive adhesive 7 does not contact the residual metal 45, thereby further avoiding the situation that the plurality of bonding electrodes 4′ are short-connected through the conductive adhesive 7 and the residual metal 45.

For example, the ratio of the dimension d1 of the edge portion 31 of the first insulating layer 3 in the second direction Y to the dimension d2 of the first bonding electrode 21 in the second direction Y is greater than or equal to ⅓ and less than or equal to ½.

With the increase of the ratio of the dimension d1 of the edge portion 31 of the first insulating layer 3 in the second direction Y to the dimension d2 of the first bonding electrode 21 in the second direction Y, as shown in FIG. 5, a region where the conductive adhesive 7 is attached in the bonding region BB is not in contact with the residual metal 45, thereby avoiding the problem that the plurality of second bonding electrodes 41 in contact with the conductive adhesive 7 in the attachment region of the conductive adhesive 7 are short-connected because the conductive adhesive 7 is in contact with the residual metal 45.

In some other embodiments, as shown in FIG. 6 and FIG. 7, the light-emitting substrate 10 further includes an insulating barrier layer disposed on a side of the second metal layer 4 away from the substrate 1. The insulating barrier layer includes an edge portion B2 located in the bonding region BB, and the edge portion B2 of the insulating barrier layer is at least located on a side of the edge portion 31 of the first insulating layer 3 away from the substrate 1. A border of the insulating barrier layer proximate to the selected side edge 1cc is closer to the selected side edge 1cc than the border of the first insulating layer 3 proximate to the selected side edge 1cc.

By providing the insulating barrier layer, a side of the edge portion 31 of the first insulating layer 3 away from the substrate 1 is enveloped, so that the side of the edge portion 31 of the first insulating layer 3 is not in contact with the conductive adhesive 7 when the conductive adhesive 7 is attached. As a result, even the residual metal 45 is generated at the border of the first insulating layer 3 proximate to the selected side edge 1cc in the production and preparation process of the light-emitting substrate 10, the problem that the plurality of second bonding electrodes 41 in contact with the conductive adhesive 7 in the attachment region of the conductive adhesive 7 are short-connected because the conductive adhesive 7 is in contact with the residual metal 45 is avoided.

It will be noted that in these embodiments, the ratio of the dimension d1 of the edge portion 31 of the first insulating layer 3 in the second direction Y to the dimension d2 of the first bonding electrode 21 in the second direction Y is not changed compared to the original design as shown in FIG. 4, and the residual metal 45 still remains in the coverage of the conductive adhesive 7. In these embodiments, by providing the insulating barrier layer, the side of the edge portion 31 of the first insulating layer 3 away from the substrate 1 is enveloped by the edge portion B2 of the insulating barrier layer 3, so that the border BJ2 of the first insulating layer 3 proximate to the selected side edge 1cc is covered by the insulating barrier layer. That is, the residual metal 45 at the border BJ2 of the first insulating layer is covered by the insulating barrier layer. As a result, the residual metal 45 and the conductive adhesive 7 are separated by the insulating barrier layer, so the two are not in contact, thereby avoiding the plurality of second bonding electrodes 41 short-connected.

In some examples, the insulating barrier layer is one of the above-mentioned passivation layers and insulating layers.

For example, as shown in FIG. 2 and FIG. 6, in the light-emitting substrate 10, the first passivation layer 5 is disposed on a side of the second metal layer 4 away from the substrate 1, the first passivation layer 5 includes a first portion located in the peripheral region AN and a second portion located in the display region AA, and the first portion of the first passivation layer 5 is at least located on a side, away from the substrate 1, of portions of the plurality of second bonding electrodes 41 proximate to the display region AA. The first portion of the first passivation layer 5 includes an edge portion 51 located in the bonding region BB, and the edge portion 51 of the first passivation layer 5 serves as the edge portion B2 of the insulating barrier layer.

The first passivation layer 5 includes the first portion located in the peripheral region AN and the second portion located in the display region AA; the first passivation layer 5 is located on the side of the second metal layer 4 away from the substrate 1, and is configured to protect the second metal layer 4, so that a surface of a portion, covered by the first passivation layer 5, of the second metal layer 4 is not easily oxidized, thereby delaying a corrosion speed of the second metal layer 4. Since portions of the plurality of second bonding electrodes 41 located in the bonding region BB are used for bonding and connecting the flexible circuit board 7′ and need to be electrically connected to the flexible circuit board 7′, in some embodiments of the related art, as shown in FIG. 4, the first passivation layer 5 does not include the edge portion 51 in the bonding region BB. In some examples of the present disclosure, a border of the first passivation layer 5 is extended into the bonding region BB, and the portion of the second metal layer 4 located in the bonding region BB is completely covered. That is to say, the edge portion 51 of the first passivation layer 5 is at least located on a side of the edge portion 31 of the first insulating layer 3 away from the substrate 1. The border of the first passivation layer 5 proximate to the selected side edge 1cc is closer to the selected side edge 1cc than the border BJ2 of the first insulating layer 3 proximate to the selected side edge 1cc, and the edge portion 51 of the first passivation layer 5 is located on a side of the residual metal 45 away from the substrate 1, so that the residual metal 45 and the conductive adhesive 7 are provided therebetween with a portion of the first passivation layer 5, thereby avoiding a contact between the residual metal 45 and the conductive adhesive 7. Moreover, the edge portion 51 of the first passivation layer 5 extending into the bonding region BB exposes the portions of the plurality of second bonding electrodes 41 for bonding the flexible circuit board 7′, and does not affect the bonding connection between the plurality of second bonding electrodes 41 and the flexible circuit board 7′.

The foregoing covering means that the second metal layer 4 is separated from other film layers on a side of the first passivation layer 5 away from the second metal layer 4, so that the second metal layer 4 is prevented from being in contact with other non-designed conductive members such as other metal film layers, causing short-connections and the like; or the second metal layer 4 is isolated from external water, air and the like, so that water and oxygen corrosion is avoided. The first passivation layer 5 and the second metal layer 4 are in direct contact or not in direct contact, which is not limited herein.

For example, as shown in FIG. 2 and FIG. 7, in the light-emitting substrate 10, the first passivation layer 5 is disposed on a side of the second metal layer 4 away from the substrate 1, and the second insulating layer 6 is disposed on a side of the first passivation layer 5 away from the substrate 1. The first passivation layer 5 includes a first portion located in the peripheral region AN, and the first portion of the first passivation layer 5 is located on a side, away from the substrate 1, of portions of the plurality of second bonding electrodes 41 proximate to the display region AA. The second insulating layer 6 includes a first portion located in the peripheral region AN, and the first portion of the second insulating layer 6 is located on a side of the first portion of the first passivation layer 5 away from the substrate 1. The first portion of the second insulating layer 6 includes an edge portion 61 located in the bonding region BB, and the edge portion 61 of the second insulating layer 6 serves as the edge portion B2 of the insulating barrier layer.

The first passivation layer 5 includes the first portion located in the peripheral region AN, and the first portion of the first passivation layer 5 is located on the side, away from the substrate 1, of the portions of the plurality of second bonding electrodes 41 proximate to the display region AA. As shown in FIG. 7, the first portion of the first passivation layer 5 located in the peripheral region AN does not include a portion between the plurality of second bonding electrodes 41 and the selected side edge 1cc (that is, the edge portion 51 of the first passivation layer 5 described above), and the first portion of the second insulating layer 6 includes the edge portion 61 located in the bonding region BB. The second insulating layer 6 is disposed on the side of the second metal layer 4 away from the substrate 1, covers the second metal layer 4, and is configured to protect the second metal layer 4, so that a surface of a portion, covered by the second insulating layer 6, of the second metal layer 4 is not easily oxidized, thereby delaying a corrosion speed of the second metal layer 4.

Since portions of the plurality of second bonding electrodes 41 located in the bonding region BB are used for bonding and connecting the flexible circuit board 7′ and need to be electrically connected to the flexible circuit board 7′, in some embodiments of the related art, as shown in FIG. 4, the second insulating layer 6 does not include the edge portion 61 in the bonding region BB. In some examples of the present disclosure, a border of the second insulating layer 6 is extended into the bonding region BB, and the portion of the second metal layer 4 located in the bonding region BB is completely covered. That is to say, the edge portion 61 of the second insulating layer 6 is at least located on a side of the edge portion 31 of the first insulating layer 3 away from the substrate 1. The border of the second insulating layer 6 proximate to the selected side edge 1cc is closer to the selected side edge 1cc than the border BJ2 of the first insulating layer 3 proximate to the selected side edge 1cc, and the edge portion 61 of the second insulating layer 6 is located on a side of the residual metal 45 away from the substrate 1, so that the residual metal 45 and the conductive adhesive 7 are provided therebetween with a portion of the second insulating layer 6, thereby avoiding a contact between the residual metal 45 and the conductive adhesive 7. Moreover, the edge portion 61 of the second insulating layer 6 extending into the bonding region BB exposes the portions of the plurality of second bonding electrodes 41 for bonding the flexible circuit board 7′, and does not affect the bonding connection between the plurality of second bonding electrodes 41 and the flexible circuit board 7′.

The foregoing covering means that the second metal layer 4 is separated from other film layers on a side of the second insulating layer 6 away from the second metal layer 4, so that the second metal layer 4 is prevented from being in contact with other non-designed conductive members such as other metal film layers, causing short-connections and the like; or the second metal layer 4 is isolated from external water, air and the like, so that water and oxygen corrosion is avoided. The second insulating layer 6 and the second metal layer 4 are in direct contact or not in direct contact, which is not limited herein.

For example, as shown in FIG. 7, the edge portion 61 of the second insulating layer 6 extends to the selected side edge 1cc.

In some examples, in various film layers as shown in FIG. 2, except for the light-emitting device and the driving chip for driving the light-emitting device to emit light, and film layers located on a side, away from the substrate 1, of the light-emitting device and the driving chip, the second insulating layer 6 is a film layer farthest from the substrate 1 in all film layer structures between the substrate 1 and both the light-emitting device and the driving chip. That is, the second insulating layer 6 envelops the remaining film layer structures on a side of the first surface 1a of the substrate 1 from a side thereof away from the substrate 1. The edge portion 61 of the second insulating layer 6 is extended to the selected side edge 1cc along the second direction Y, the film layer structures on the side of the first surface 1a of the substrate 1 may be enveloped in the second insulating layer 6, thereby effectively avoiding a contact between external air, water and the like and the film layer structures between the substrate 1 and the second insulating layer 6. Mechanical damage to the film layer structures on the side of the first surface 1a of the substrate 1 may be effectively avoided, and film layers of a metal material on the side of the first surface 1a of the substrate 1 may also be effectively prevented from water and oxygen corrosion, thus the second insulating layer 6 may play a role in protecting the film layers of the metal material on the side of the first surface 1a of the substrate 1, such as the first metal layer 2 and the second metal layer 4.

For example, as shown in FIG. 5, FIG. 6 and FIG. 7, the second metal layer 4 further includes a residual metal 45 located in the bonding region BB, the residual metal 45 is located at a border of the first insulating layer 3 proximate to the selected side 1cc, and the residual metal 45 extends along the first direction X. The conductive adhesive 7 is electrically insulated from the residual metal 45.

As described above, when the second metal layer 4 is formed on a side of the first insulating layer 3 away from the first metal layer 2, there is a height difference (the cross-sectional shape of the edge portion of the first insulating layer 3 has a bevel edge) between the border of the first insulating layer 3 proximate to the selected side edge 1cc and the portion of the first insulating layer 3 proximate to the second bonding electrode 41, and therefore, when the conductive pattern in the second metal layer 4 is formed, the residual metal 45 is easily generated at a position of the border of the edge portion 31 of the first insulating layer 3 proximate to the selected side edge 1cc. When the conductive adhesive 7 is in contact with the residual metal 45, because the residual metal 45 is a linear metal extending along the first direction X, after the flexible circuit board 7′ is bonded, a portion, in contact with the conductive adhesive 7, of the linear residual metal 45, the flexible circuit board 7′, and the plurality of second bonding electrodes 41 bonded to the flexible circuit board 7′ form a loop, which causes the plurality of second bonding electrodes 41 to be short-connected, so that the light-emitting substrate 10 cannot normally receive control signals, affecting normal operation of the light-emitting substrate 10. The contact between the conductive adhesive 7 and the residual metal 45 means that the conductive adhesive 7 covers at least a portion of the residual metal 45.

The conductive adhesive 7 being electrically insulated from the residual metal 45 means that the conductive adhesive 7 is not in physical contact with or electrically connected to the residual metal 45, thereby preventing adjacent second bonding electrodes 41 from being short-connected. In the above embodiments, the dimension of the edge portion 31 of the first insulating layer 3 is increased, and the insulating barrier layer is arranged such that the conductive adhesive 7 is electrically insulated from the residual metal 45.

The related contents of the display region AA of the light-emitting substrate 10 are described below.

In some embodiments, as shown in FIG. 1 and FIG. 8A to FIG. 11, the display region AA includes display unit regions P, and the display unit region P includes a light-emitting zone CC and a driving zone CN. The first metal layer 2 includes a plurality of first signal lines 22 located in the display region AA, the plurality of first signal lines 22 do not pass through the driving zone CN, and at least one first signal line 22 passes through the light-emitting zone CC.

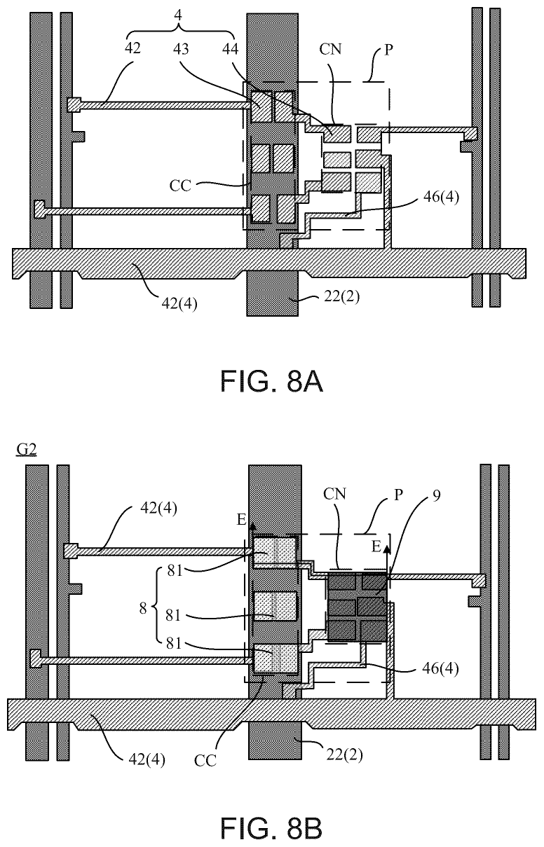

As shown in FIG. 1, FIG. 8A and FIG. 8B, the display region AA includes a plurality of display unit regions P, the plurality of display unit regions P are arranged in an array, and each display unit region P includes a light-emitting zone CC and a driving zone CN. The plurality of first signal lines 22 are located in the first metal layer 2 and extend along the second direction Y. For example, multiple display unit regions P arranged in a column along the second direction Y are electrically connected to a group of first signal lines 22, and the group of first signal lines 22 includes N first signal lines 22. For example, the group of first signal lines 22 includes five first signal lines, where the third signal line in the five first signal lines 22 passes through light-emitting zones CC in the multiple display unit regions P arranged in the column, and none of the five first signal lines 22 passes through driving zones CN in the multiple display unit regions P arranged in the column. The light-emitting substrate 10 further includes a plurality of second signal lines 42, and the plurality of second signal lines 42 extend along the first direction X, For example, multiple display unit regions P arranged in a row along the first direction X are electrically connected to a second signal line 42.

As shown in FIG. 8B, the light-emitting substrate 10 further includes light-emitting device groups 8 each located in a light-emitting zone CC, and driving chips 9 each located in a driving zone CN. The light-emitting device group 8 is disposed on a side of the second metal layer 4 away from the substrate 1 and electrically connected to the second metal layer 4. An orthographic projection of the light-emitting device group 8 on the substrate 1 is within an orthographic projection of a portion of at least one first signal line 22 passing through the light-emitting zone CC on the substrate 1. The driving chip 9 is disposed on the side of the second metal layer 4 away from the substrate 1, and the driving chip 9 is electrically connected to the light-emitting device group 8. In a display unit region P, the driving chip 9 is electrically connected to the light-emitting device group 8, and the driving chip 9 is configured to control the light-emitting device group 8 electrically connected thereto to emit light.

As shown in FIG. 8A, in some examples, the second metal layer 4 further includes a plurality of light-emitting bonding pads 43 located in each light-emitting zone CC and a plurality of driving bonding pads 44 located in each driving zone CN, and a plurality of connection lines 46. The light-emitting device group 8 includes a plurality of light-emitting devices 81, each pin of the light-emitting device 81 is electrically connected to a light-emitting bonding pad 43, and each pin of the driving chip 9 is electrically connected to a driving bonding pad 44. The plurality of connection lines 46 are configured to connect the bonding pads and the signal lines, or are configured to connect the driving bonding pads 44 and the light-emitting bonding pads 43. Each driving chip 9 is configured to control a light-emitting device group 8 to work, and is configured to control the light-emitting device group 8 to emit light or be turned off, and an intensity of luminescence of the light-emitting device group 8.

In some examples, each light-emitting device group 8 includes light-emitting devices 81 of at least three colors, the light-emitting devices 81 of various colors include at least a light-emitting device of a first color, a light-emitting device of a second color, and a light-emitting device of a third color, the first color, the second color, and the third color are three primary colors (e.g., red, green, and blue).

The light-emitting device 81 includes but is not limited to a Mini LED (Mini Light-emitting Diode), a Micro LED (Micro Light-emitting Diode), or the like.

The light-emitting device group 8 can emit different colors under the control of the driving chip 9, for example, black, white or colors. The mini LED or micro LED may serve as the light-emitting device 81. Due to a small size of the light-emitting device 81, human eyes can see display images from the side of the first surface 1a of the light-emitting substrate 10.

Compared with the conventional LED, the size of the light-emitting device 81 adopting the mini LED or micro LED is smaller, a density is higher, display images are finer, a visible distance is small, and a viewing angle is larger, where the viewing angle may reach 160 degrees or more.

In some examples, the substrate 1 is made of a transparent material such as glass. The display images may be visible from both the first surface 1a of the light-emitting substrate 10 and the other side opposite to the first surface 1a.

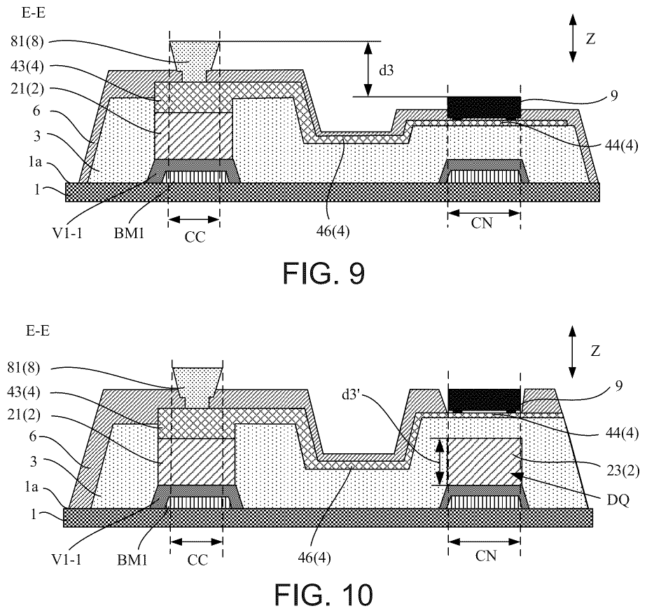

In order to improve a transmittance of the light-emitting substrate 10, so that the display images may be more clearly seen from the other side opposite to the first surface 1a of the light-emitting substrate 10, a width of the first signal line is reduced while a thick copper layer is formed as the first metal layer by an electroplating process. In some embodiments, the light-emitting device group 8 is disposed on a side of the first signal line 22 away from the substrate 1, so that the transmittance of the light-emitting substrate may be increased. For example, each light-emitting device group in display unit regions P arranged in a column is located on a side of a first signal line 22 away from the substrate 1, and is connected to the first signal line 22 through light-emitting bonding pads 43. The first signal line 22 is configured to transmit a signal, for example, the first signal line 22 transmits a ground signal GND. For wiring reasons, the driving chip 9 is not disposed on the first signal line 22, that is, the driving chip 9 and the substrate 1 are not provided therebetween with a conductive pattern of the first metal layer 2. As shown in FIG. 9, a distance between the light-emitting device group 8 and the substrate 1 is greater than a distance between the driving chip 9 and the substrate 1. That is, in a direction Z perpendicular to the first surface 1a of the substrate 1, a height difference d3 exists between a plane where a side of the light-emitting device group 8 away from the substrate 1 is located and a plane where a side of the driving chip 9 away from the substrate 1 is located. The height difference d3 is, for example, 7 μm. Due to the existence of the height difference d3, an abnormality will occur in a subsequent planarization process and an assembly process, resulting in a bad point in the light-emitting device 81 or an abnormal bonding of the driving chip, and a driving abnormality.

In some examples, when the first metal layer 2 is prepared, a first conductive film layer is firstly formed by an electroplating process, and the first conductive film layer is made of a metal material with good conductivity, such as pure copper; then, a conductive pattern is formed in the first conductive film layer by a photolithography process. The conductive pattern formed in the first conductive film layer is the plurality of first bonding electrodes 21 and the plurality of first signal lines 22 included in the first metal layer 2.

In some examples, when the second metal layer 4 is prepared, a second conductive film layer is formed by a magnetron sputtering process, and the second conductive film layer is made of a metal material with good conductivity and good corrosion resistance, such as a copper-nickel alloy; then, a conductive pattern is formed in the second conductive film layer by a photolithography process. The conductive pattern formed in the second conductive film layer is the plurality of second bonding electrodes 41 and the plurality of second signal lines 42 included in the second metal layer 4.

The electroplating process, the magnetron sputtering process and the photolithography process adopted in the processes of preparing the first metal layer 2 and the second metal layer 4 are only examples of the process, and are not limited by the process in the actual preparation process.

In the above embodiments, the first conductive film layer for preparing the first metal layer 2 is prepared by the electroplating process, the obtained first metal layer 2 is relatively thick, and a target thickness may be achieved; in some other embodiments, the first conductive film layer is prepared by the magnetron sputtering process, and the obtained first metal layer 2 may also have the target thickness.

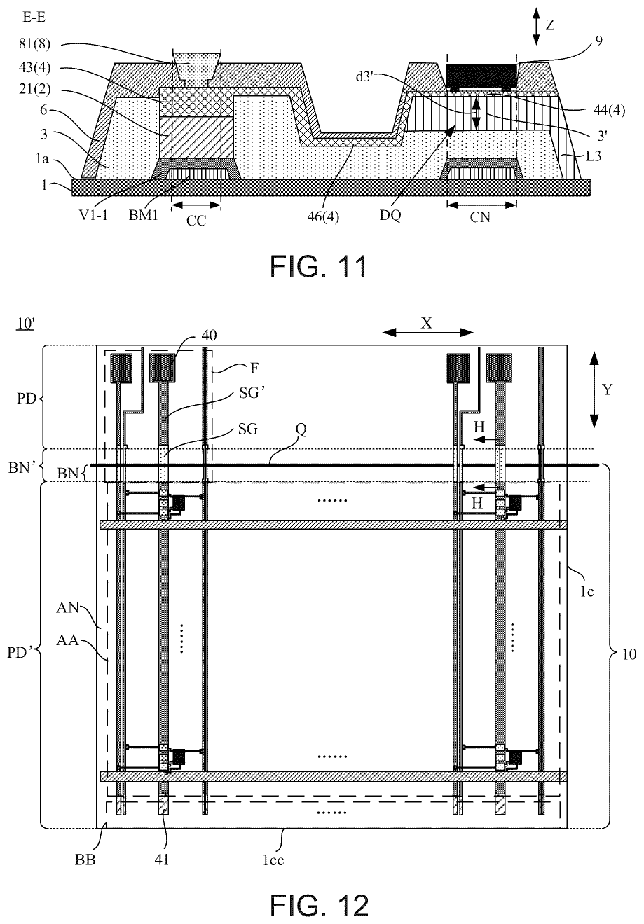

In some embodiments, as shown in FIG. 10 and FIG. 11, the light-emitting substrate 10 further includes at least one prop structure DQ disposed in the driving zone CN and located between the driving chip 9 and the substrate 1. The prop structure DQ is configured to increase a distance between the driving chip 9 and the substrate 1, so that a distance between the driving chip 9 and the substrate 1 is equal to a distance between the light-emitting device group 8 connected to the driving chip 9 and the substrate 1.

For example, as shown in FIG. 10 and FIG. 11, each display unit region P is provided with a prop structure DQ, the prop structure DQ is disposed in the driving zone CN, and is located between the driving chip 9 and the substrate 1, so that a distance between the driving chip 9 and the substrate 1 is equal to a distance between the light-emitting device group 8 connected to the driving chip 9 and the substrate 1.

For example, as shown in FIG. 10 and FIG. 11, a thickness d3′ of the prop structure DQ in a direction Z perpendicular to a plane where the substrate 1 is located is substantially equal to the height difference d3.

By arranging the prop structure DQ between the driving chip 9 and the substrate 1 as a structure for compensating the height difference d3, the distance between the driving chip 9 and the substrate 1 is increased, so that the distance between the driving chip 9 and the substrate 1 is equal to or substantially equal to the distance between the light-emitting device group 8 connected to the driving chip 9 and the substrate 1, the height difference d3 may be eliminated, the abnormal situation caused by the height difference d3 may be eliminated, thereby ensuring a normal connection between the driving chip 9 and the light-emitting device group 8, and a normal operation of the light-emitting device group 8 and the driving chip 9. The prop structure DQ is only disposed between the driving chip 9 and the substrate 1, and does not increase a thickness of the light-emitting substrate 10 in the third direction Z perpendicular to the first surface 1a while the effect for compensating the height difference d3 is achieved.

For example, as shown in FIG. 10, the first metal layer 2 further includes pads 23 each located in the driving zone CN, and the pad 23 serves as a prop structure DQ. The pad 23 is electrically insulated from the plurality of first signal lines 22 and the plurality of first bonding electrodes 21, and the pad 23 is electrically insulated from the second metal layer 4. An orthographic projection of the driving chip 9 on the substrate 1 is within an orthographic projection of the pad 23 on the substrate 1.

Further, the pad 23 is electrically insulated from conductive structures in the light-emitting substrate 10. The pad 23 only serves as a structure for compensating the height difference, and is electrically insulated from the conductive structures, such as the first metal layer 2 and the second metal layer 4, in the light-emitting substrate 10.

When the first metal layer 2 is prepared, the pad 23 is formed at a mounting position of the driving chip 9, and the pad 23 is not in contact with the second metal layer 4, and other portions of the first metal layer 2, such as the first bonding electrode 21 and the first signal line 22. That is, the pad 23 in the first metal layer 2 only serves as the structure for compensating the height difference, and does not transmit signals. It can be understood that the pad 23 is a redundancy design of the first metal layer 2. Moreover, an area of the pad 23 is equal to or substantially equal to an area of the driving chip 9. In some examples, the area of the pad 23 is equal to the area of the driving chip 9. In some other examples, the area of the pad 23 is slightly greater than the area of the driving chip 9. In this way, In this way, while raising the driving chip 9, effectively reducing the height difference d3 between the light-emitting device group 8 and the driving chip 9, it may also ensure that the transmittance of the light-emitting substrate 10 is not affected.

For example, as shown in FIG. 11, the light-emitting substrate 10 further includes a third insulating layer L3, the third insulating layer L3 includes at least one insulating structure 3′ located in each driving zone CN, and the insulating structure 3′ serves as a prop structure DQ. An orthographic projection of the driving chip 9 on the substrate 1 is within an orthographic projection of the insulating structure 3′ on the substrate 1.

As a possible design, the third insulating layer is made of a transparent insulating material, such as silicon nitride.

In some embodiments, as shown in FIG. 11, the third insulating layer L3 is located between the first insulating layer 3 and the second metal layer 4.

In some other embodiments, the third insulating layer is located between the substrate 1 and the first insulating layer 3.

The driving chip 9 is connected to driving bonding pads 44, so the insulating structure serves as the prop structure DQ, as long as it is located between the driving bonding pad 44 and the substrate 1. Therefore, the third insulating layer may be formed on a side of the first insulating layer 3 proximate to the substrate 1, that is, a step of forming the third insulating layer is before a step of forming the first insulating layer 3; alternatively, the third insulating layer is located between the first insulating layer 3 and the second metal layer 4, that is, a step of forming the third insulating layer is after a step of forming the first insulating layer 3, and before a step of forming the second metal layer 4.

In some embodiments, in the manufacturing process of the light-emitting substrate, an initial light-emitting substrate 10′ is first formed, the initial light-emitting substrate 10′ includes a test region PD, a cutting channel region BN′ and a reserved region PD′, where the cutting channel region BN′ is connected to the test region PD and the reserved region PD′. The test region PD is provided therein with a plurality of test traces SG′ and a plurality of test pads 40. The reserved region PD′ includes the display region AA and the bonding region BB. As shown in FIG. 1 and FIG. 12, the light-emitting substrate 10 is finally obtained by cutting away the test region PD from the initial light-emitting substrate 10′ along a cutting line Q, where the cutting line Q is a line extending along the first direction X in the cutting channel region BN′. In the cutting channel region BN′, a region at a side of the cutting line Q proximate to the display region AA is a cut-off region BN.

A substrate in the initial light-emitting substrate 10′ including the test region PD is referred to as an initial substrate 1′. It can be understood that the substrate 1 is obtained by cutting away a portion corresponding to the test region PD from the initial substrate 1′, so the first surface 1a of the substrate 1 and a first surface of the initial substrate 1′ are a same surface, and the selected side edge 1cc of the substrate 1 and a selected side edge of the initial substrate 1′ are a same side edge. In the initial light-emitting substrate 10′, the cutting channel region BN′ is connected to the test region PD. The initial light-emitting substrate 10′ has a plurality of initial test connection lines SG, and the plurality of initial test connection lines SG are configured to connect the test region PD and the reserved region PD. Ends of the initial test connection lines SG extend into the test region PD, and are connected to ends of the test traces SG′; and the other ends of the initial test connection lines SG extend into the display region of the reserved region PD′, and are electrically connected to the first signal lines 22. For example, the plurality of test traces SG′ are located in the first metal layer 2, and the other ends of the plurality of test traces SG′ are located on a side of the test region PD away from the cut-off region BN, and are connected to the test pads 40. The test region PD and film layer structures in the test region PD, for example, the plurality of test traces SG′ and the test pads 40, are configured to perform signal transmission test on the light-emitting substrate 10 before bonding the flexible circuit board 7′ to detect whether the plurality of first signal lines 22, the plurality of second signal lines 42 in the light-emitting substrate 10 can normally transmit data signals, and whether the driving chip 9 can normally drive the light-emitting device group 8 to operate.

After the test is completed, the test region PD is cut away along the cutting line Q to obtain the light-emitting substrate 10, and then the flexible circuit board 7′ is bonded to the light-emitting substrate 10. As shown in FIG. 1, the light-emitting substrate 10 has the display region AA and the peripheral region AN located around the display region AA, the peripheral region AN includes the cut-off region BN and the bonding region BB, and the cut-off region BN and the bonding region BB are located at different sides of the display region AA. The light-emitting substrate 10 further includes a plurality of test connection lines SG1 (the test connection lines SG1 are obtained after the initial test connection lines SG are cut off). Ends of the plurality of test connection lines SG1 are located in the display region AA, and the other ends of the plurality of test connection lines SG1 extend into the cut-off region BN and are flush with a border of the cut-off region BN away from the display region AA.

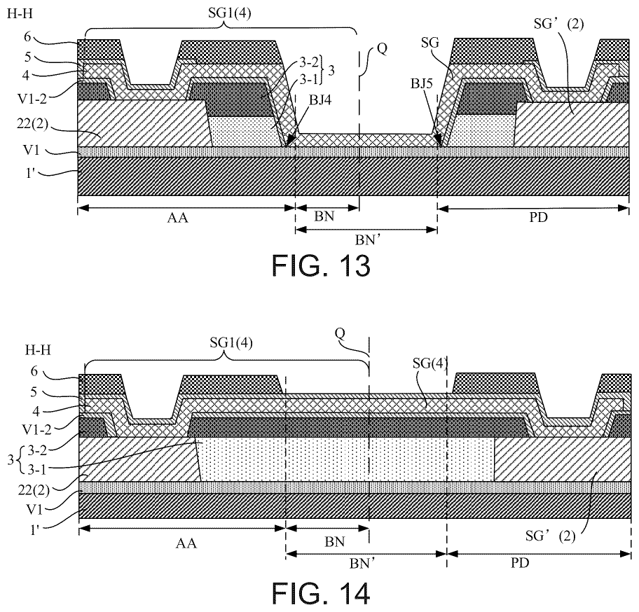

In some examples, as shown in FIG. 12, the bonding region BB and the cut-off region BN are located on opposite sides of the display region AA, and an extension direction of the cut-off region BN is consistent with that of the bonding region BB, that is, the cut-off region BN extends along the first direction X. As shown in FIG. 13, when the cutting channel region BN′ is cut along the cutting line Q, in order to facilitate the cutting and prevent the cutting defect, a thickness of each film layer located in the cutting channel region BN′ needs to be reduced as much as possible. For example, in the initial light-emitting substrate 10′, the first insulating layer 3 is located in the display region AA and the test region PD, and is not located in the cutting channel region BN′, that is, there are two borders of portions of the first insulating layer 3 proximate to the cut-off region BN. That is, a portion of the first insulating layer 3 is located in the display region AA, the other portion of the first insulating layer 3 is located in the test region PD, where the two borders are a border BJ4 of the portion proximate to a side of the cut-off region BN, and a border BJ5 of the other portion proximate to another side of the cut-off region BN.

For example, a maximum dimension of the first insulating layer 3 in a direction perpendicular to the substrate 1 is, for example, 10 μm.

In some embodiments, the initial test connection lines SG are located in the second metal layer 4, and both ends of an initial test connection line SG are electrically connected to a first signal line 22 and a test trace SG′ located in the first metal layer 2 through via holes.

A preparation method of the second metal layer 4 includes, for example, firstly, forming a conductive film layer by an electroplating process or a sputtering process, where the conductive film layer adopts a metal material with good electrical conductivity, such as copper; then, etching the conductive film layer by a photolithography process, thereby forming a conductive pattern in the conductive film layer. The conductive pattern refers to the plurality of second signal lines 42, the test connection lines SG1 and the like included in the second metal layer 4. The electroplating process, the sputtering process, and the photolithography process described above are only examples of the process used in the preparation method, and are not limited by the process in the actual preparation process.

In the preparation process of the second metal layer 4, since there are a height difference at the border BJ4, located in the display region AA and proximate to the side of the cut-off region BN, of the first insulating layer 3, and a height difference at the border BJ5, located in the test region PD and proximate to the side of the cut-off region BN, of the first insulating layer 3, when the second metal layer 4 is prepared, portions of the conductive film layer for preparing the second metal layer 4 that should be removed by the photolithography process are easily left at the border BJ4 and the border BJ5 of the first insulating layer 3, that is, the second metal layer 4 further includes residual traces located at the border BJ4 and the border BJ5 of the first insulating layer 3. An extension direction of the residual traces is consistent with the extension direction of the cut-off region BN, that is, the residual traces extend along the first direction X. In a microscope image of the light-emitting substrate 10, the residual traces appear as two bright lines, at the border BJ4 and the border BJ5 of the first insulating layer 3, in the second metal layer 4, that is, the residual traces are strip-shaped continuous patterns extending along the first direction X. It can be understood that the residual traces at the border BJ4, located in the display region AA and proximate to the side of the cut-off region BN, of the first insulating layer 3, and at the border BJ5, located in the test region PD and proximate to the side of the cut-off region BN, of the first insulating layer 3 are portions that need to be removed by processes or avoided by other design, rather than portions that need to be reserved in the product design.

In a case that the residual traces exist, a residual trace at the border BJ4 of the first insulating layer 3 may cause the plurality of initial test connection lines SG to be short-connected through the residual trace, that is, at least two of the plurality of initial test connection lines SG are connected through the residual trace, thereby forming a loop; and/or a residual trace at the border BJ5 of the first insulating layer 3 may cause the plurality of initial test connection lines SG to be short-connected through the residual trace, that is, at least two of the plurality of initial test connection lines SG are connected through the residual trace, thereby forming a loop. As a result, the driving signal provided by the external driver chip cannot be normally transmitted to the display region AA, so that when the plurality of test traces SG′ and the test pads 40 perform signal transmission test on the display region, signal abnormality occurs, affecting the normal operation of the initial light-emitting substrate 10′, for example, a large region of uncontrollable lines appears, which appears as a blurry screen. Further, after the test region is cut off, the obtained light-emitting substrate 10 may also have a problem of abnormal display because the plurality of test connection lines SG1 are short-connected at the border BJ4 of the first insulating layer 3 due to, and occurs.

In light of this, some embodiments of the present disclosure provide some structural design on the cutting channel region BN′ to solve the problem of short-connecting the test connection lines SG and/or the test traces SG′.

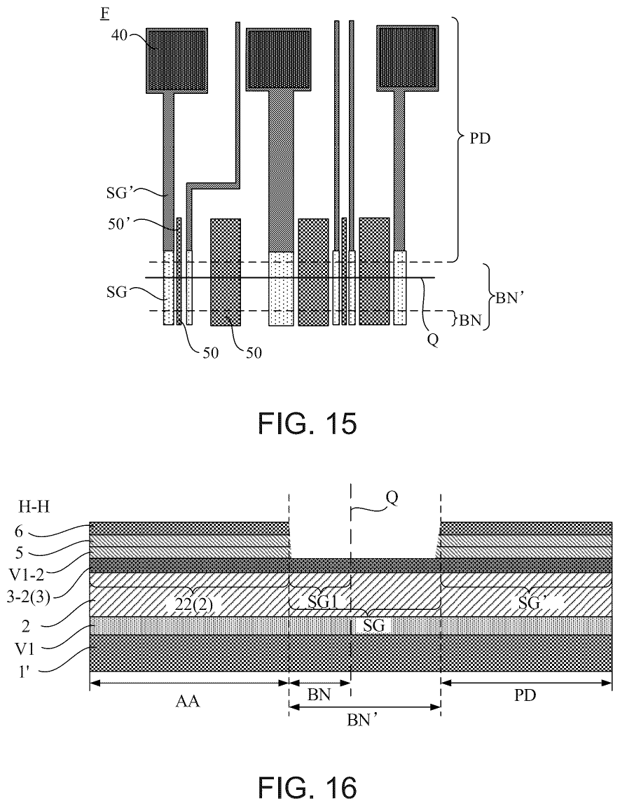

In some examples, as shown in FIG. 14 and FIG. 15, the light-emitting substrate 10 has the display region AA and the peripheral region AN located around the display region AA, the peripheral region AN includes the cut-off region BN and the bonding region BB, and the cut-off region BN and the bonding region BB are located at different sides of the display region AA. The light-emitting substrate 10 further includes the plurality of test connection lines SG1 and a protection structure located in the second metal layer 4, the plurality of test connection lines SG1 are located in the second metal layer 4, ends of the plurality of test connection lines SG1 are located in the display region AA, the other ends of the plurality of test connection lines SG1 extend into the cut-off region BN and are flush with a border of the cut-off region BN away from the display region AA. The protection structure is configured to prevent the plurality of test connection lines SG1 from being short-connected.

In the above embodiments, the test connection lines SG1 (the initial test connection lines SG) are still disposed in the second metal layer 4, and the protection structure is provided to prevent the plurality of test connection lines SG from being short-connected to affect the normal operation of the light-emitting substrate 10.

For example, as shown in FIG. 14, the first insulating layer 3 further extends to the cut-off region BN, a border of the first insulating layer 3 proximate to the cut-off region BN is flush with the border of the cut-off region BN away from the display region AA, and a portion of the first insulating layer 3 extending to the cut-off region BN serves as the protection structure.

In some examples, the first insulating layer 3 includes a first insulating sub-layer 3-1 and a second insulating sub-layer 3-2, and both the first insulating sub-layer 3-1 and the second insulating sub-layer 3-2 extend to the cut-off region BN, and borders of the two proximate to the cut-off region BN are flush with the border of the cut-off region BN away from the display region AA.

It can be understood that, in the preparation process of the light-emitting substrate 10, in the initial light-emitting substrate 10′ having the test region PD, the first insulating layer 3 is also disposed in the cutting channel region BN′, that is, the first insulating layer 3 is continuously formed in the display region AA, the cutting channel region BN′ and the test region PD, so there is no recess formed in the cutting channel region BN′. That is, for a portion of the second metal layer 4 in the cutting channel region BN′, a portion of the second metal layer 4 in the display region AA, and a portion of the second metal layer 4 in a portion of the test region PD proximate to the cutting channel region BN′, a distance between each of the portions and the substrate 1 is same or substantially same, so there is no height difference. Therefore, when the plurality of initial test connection lines SG are formed, there is no additional residual trace generated in the second metal layer 4, thereby avoiding a short-connection between the plurality of initial test connection lines SG. Moreover, after the test region PD is cut away along the cutting line Q, the plurality of test connection lines SG1 are also not short-connected. It can be understood that, in the initial light-emitting substrate 10′, the first insulating layer 3 is continuously formed in the display region AA, the cutting channel region BN′ and the test region PD, so that after the initial light-emitting substrate 10′ is cut along the cutting line Q, the first insulating layer 3 further extends to the cut-off region BN, and a border of the first insulating layer 3 proximate to the cut-off region BN is flush with the border of the cut-off region BN away from the display region AA.

In some other examples, the first insulating layer 3 does not extend to the cut-off region BN. As shown in FIG. 15, the light-emitting substrate 10 further includes a plurality of isolation retaining walls 50 located in the cut-off region BN. The isolation retaining walls 50 are made of an insulating material and serve as the protection structure. Each isolation retaining wall 50 is disposed between two adjacent test connection lines SG1.

By arranging an isolation retaining wall 50 made of an insulating material between two adjacent test connection lines SG1, the two adjacent test connection lines SG1 may be effectively separated, thereby avoiding the short-circuit caused by contact between the two adjacent test connection lines SG1.

In some examples, in the manufacturing process of the light-emitting substrate 10, a step of forming the isolation retaining walls 50 is before a step of forming the second metal layer 4. In combination with FIG. 13 and FIG. 15, an end of the isolation retaining wall 50 is located in the cut-off region BN, and the other end of the isolation retaining wall 50 extends to the border BJ4 of the first insulating layer 3 located in the display region AA and proximate to a side of the cut-off region BN. An extension direction of the isolation retaining wall 50 is consistent with an extension direction of the test connection line SG. In the initial light-emitting substrate 10′ having the test region PD, the initial light-emitting substrate 10′ further includes trace retaining walls 50′, an end of the trace retaining wall 50′ is located in the cutting channel region BN′, and the other end of the trace retaining wall 50′ extends to the border BJ5 of the first insulating layer 3 located in the test region PD and proximate to a side of the cutting channel region BN′. Therefore, when the second metal layer 4 is formed in the initial light-emitting substrate 10′ having the test region PD, even the residual traces are generated at the borders (the border BJ4 and the border BJ5) of the first insulating layer 3, adjacent test connection lines SG may be effectively separated due to an existence of the isolation retaining wall 50, thereby avoiding the short-connection between the plurality of test connection lines SG. Arranging the trace retaining wall 50′ may effectively avoid the short-connection between the plurality of test traces SG′.

Further, an isolation retaining wall 50 and a trace retaining wall 50′ are of an integral structure. That is, an end of the isolation retaining wall 50 located in the cut-off region BN is connected to an end of the trace retaining wall 50′ located in the dicing street region BN′.

For example, a dimension of the isolation retaining wall 50 in a direction perpendicular to the substrate 1 is not less than 3 μm. The dimension of the isolation retaining wall 50 in the direction perpendicular to the substrate 1 is, for example, 3 μm, 4 μm, or 5 μm.

In some examples, the isolation retaining walls are disposed on the first surface 1a of the substrate 1.

In some other examples, a buffer layer is disposed on a side of the first surface 1a of the substrate 1, the buffer layer is located between the first metal layer 2 and the substrate 1, and the isolation retaining walls are disposed on a surface of the first metal layer 2 away from the substrate 1.

In yet some other examples, as shown in FIG. 16, the light-emitting substrate 10 further includes a plurality of test connection lines SG1 located in the first metal layer 2, ends of the plurality of test connection lines SG1 are located in the display region AA, and the other ends of the plurality of test connection lines SG1 extend to the cut-off region BN and are flush with a border of the cut-off region BN away from the display region AA.

In the initial light-emitting substrate 10′, by arranging the initial test connection lines SG in the first metal layer 2, the first insulating layer 3 is located on a side of the first metal layer 2 away from the substrate, the initial test connection line SG enters the test region PD from the display region AA through the cutting channel region BN′, and a distance between a surface of the initial test connection line SG and the substrate at various positions is same, so that the metal residue caused by the height difference does not occur, the problem of the short-connection of the plurality of initial test connection lines SG through the residual metal does not occur, and moreover, the problem of the short-connection of the plurality of initial test connection lines SG due to the metal residue of the second metal layer is avoided because no cross-line design is performed on the second metal layer.

In this way, in the light-emitting substrate 10 obtained by cutting the initial light-emitting substrate 10′ along the cutting line Q, the plurality of test connection lines SG1 are located in the first metal layer 2, ends of the plurality of test connection lines SG1 are located in the display region AA, and the other ends of the plurality of test connection lines SG1 extend to the cut-off region BN and are flush with a border of the cut-off region BN away from the display region AA.

Some embodiments of the present disclosure provide a light-emitting substrate 10, as shown in FIG. 1, FIG. 10 and FIG. 11, the light-emitting substrate 10 has a display region AA, where the display region AA includes display unit regions P, and the display unit region P includes a light-emitting zone CC and a driving zone CN. The light-emitting substrate 10 includes a substrate 1, a first metal layer 2 disposed on a side of a first surface 1a of the substrate 1, a first insulating layer 3 disposed on a side of the first metal layer 2 away from the substrate 1, a second metal layer 4 disposed on a side of the first insulating layer 3 away from the first metal layer 2, light-emitting device groups 8 each disposed in a light-emitting zone CC, driving chips 9 each disposed in a driving zone CN, and prop structures DQ each located in a driving zone CN. The first metal layer 2 includes a plurality of first signal lines 22 located in the display region AA, the plurality of first signal lines 22 do not pass through the driving zone CN, and at least one first signal line 22 passes through the light-emitting zone CC. The second metal layer 4 includes a plurality of second signal lines 42 located in the display region AA. The light-emitting device group 8 is disposed on a side of the second metal layer 4 away from the substrate 1 and electrically connected to the second metal layer 4, and an orthographic projection of the light-emitting device group 8 on the substrate 1 is within an orthographic projection of a portion of the at least one first signal line 22 passing through the light-emitting zone CC on the substrate 1. The driving chip 9 is disposed on the side of the second metal layer 4 away from the substrate 1, and is electrically connected to the second metal layer 4 and the light-emitting device group 8 respectively. The prop structure DQ is disposed between the driving chip 9 and the substrate 1, and is configured to increase a distance between the driving chip 9 and the substrate 1, so that the distance between the driving chip 9 and the substrate 1 is equal to a distance between the light-emitting device group 8 connected to the driving chip 9 and the substrate 1.

For example, as shown in FIG. 10, the first metal layer 2 further includes pads 23 each located in the driving zone CN, and the pad 23 serves as a prop structure DQ. The pad 23 is electrically insulated from the plurality of first signal lines 22, and the pad 23 is electrically insulated from the second metal layer 4. An orthographic projection of the driving chip 9 on the substrate 1 is within an orthographic projection of the pad 23 on the substrate 1.

For example, as shown in FIG. 11, the light-emitting substrate 10 further includes a third insulating layer, the third insulating layer includes at least one insulating structure 3′ located in each driving zone CN, the insulating structure 3′ serves as a prop structure DQ. An orthographic projection of the driving chip 9 on the substrate 1 is within an orthographic projection of the insulating structure 3′ on the substrate 1.

The beneficial effects of the light-emitting substrate 10 of the present solution are same as those of the light-emitting substrate 10, which will not be repeated here.

For example, the light-emitting device group 8 includes a plurality of light-emitting devices 81, the light-emitting devices 81 are light-emitting diodes, and the light-emitting diodes are mini light-emitting diodes or micro light-emitting diodes.

The mini light-emitting diodes are commonly referred to as mini LEDs, and the micro light-emitting diodes are commonly referred to as Micro LEDs. The mini light-emitting diode or the micro light-emitting diode serves as the light-emitting device 81, so compared with a conventional LED, the mini LED or micro LED chip size may reach a micron scale, and have a smaller occupied volume and smaller particles. In a same screen size, a density of a light source per unit area is higher and a unit size of the light source is smaller, so that more precise local control may be realized on the light-emitting devices 81 in the plurality of light-emitting device groups 8 in the light-emitting substrate 10, accurate light control may be realized, and a problem of non-uniform brightness of the light-emitting device 81 may be avoided; and the display image gray scale is good, and the power consumption is low.

The structural design of the display region and the peripheral region (such as the bonding region and the cut-off region) of the light-emitting substrate provided by these embodiments are same as the structural design of the light-emitting substrate 10, and details are not described herein again.

Some embodiments of the present disclosure provide a light-emitting substrate 10, as shown in FIG. 2, FIG. 14 and FIG. 15, the light-emitting substrate 10 has a display region AA and a peripheral region AN located around the display region AA, and the peripheral region AN includes a cut-off region BN. The light-emitting substrate 10 includes a substrate 1, a first metal layer 2, a first insulating layer 3, a second metal layer 4, and a protection structure. The first metal layer 2 is disposed on a side of a first surface of the substrate 1. The first insulating layer 3 is disposed on a side of the first metal layer 2 away from the substrate 1. The second metal layer 4 is disposed on a side of the first insulating layer 3 away from the first metal layer 2, which includes a plurality of test connection lines SG. Ends of the plurality of test connection lines SG are located in the display region AA, and the other ends of the plurality of test connection lines SG extend to the cut-off region BN and are flush with a border of the cut-off region BN away from the display region AA. The protection structure is configured to prevent the plurality of test connection lines SG from being short-connected.

For example, as shown in FIG. 14, the first insulating layer 3 further extends to the cut-off region BN, a border of the first insulating layer 3 proximate to the cut-off region BN is flush with a border of the cut-off region BN away from the display region AA, and a portion of the first insulating layer 3 extending to the cut-off region BN serves as the protection structure.

For example, the first insulating layer 3 does not extend to the cut-off region BN. As shown in FIG. 15, the light-emitting substrate 10 further includes a plurality of isolation retaining walls 50 located in the cut-off region BN. The isolation retaining walls 50 are made of an insulating material as the protection structure. Each isolation retaining wall 50 is disposed between two adjacent test connection lines SG.

By providing the protection structure, the problem that the plurality of test connection lines SG are short-connected to affect normal operation of the light-emitting substrate 10 is avoided.

The structural design of the display region and the peripheral region (such as the bonding region and the cut-off region) of the light-emitting substrate provided by these embodiments are same as the structural design of the light-emitting substrate 10, and details are not described herein again.

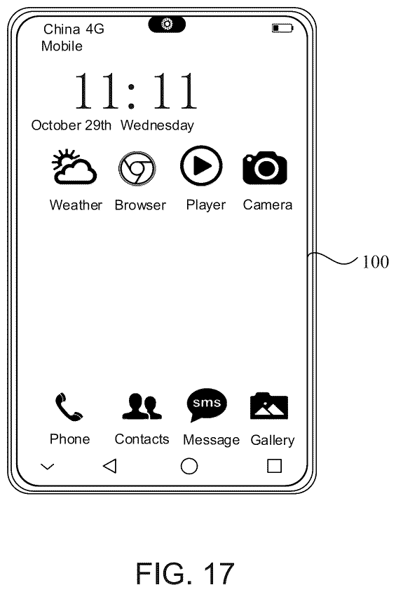

As shown in FIG. 17, some embodiments of the present disclosure provide a display apparatus 100, which includes the light-emitting substrate 10 according to any one of the above embodiments.

In some embodiments, the light-emitting substrate 10 is applied to a display, that is, the light-emitting substrate 10 directly serves as a display panel, and can display images. The display apparatus 100 is an active light-emitting display apparatus. In this case, since the light-emitting substrate 10 can emit light, a backlight module does not need to be additionally arranged, and the light-emitting substrate 10 can directly serve as the display panel to display an image to be displayed. The image to be displayed is a target display image of the display apparatus 100, which may be an all-black, all-white, or color image. For example, the display apparatus 100 is a transparent display apparatus, the substrate 1 is made of a transparent material, and the substrate 1 is, for example, glass. The glass serves as the substrate 1, so that bidirectional light transmission may be realized, and the glass can be applied to an indoor screen, a transparent display screen and the like.

The display apparatus 100 uses the light-emitting substrate 10 as a display panel, the display region of the light-emitting substrate 10 is provided with a plurality of pixels, each pixel includes a light-emitting device group 8 and a pixel driving chip, and each pixel driving chip is connected to a light-emitting device group for driving the light-emitting device group to operate. Each pixel includes at least three sub-pixels, and each sub-pixel includes at least one light-emitting device, such as a mini light-emitting diode or a micro light-emitting diode. Considering an example in which each pixel includes three sub-pixels, and each sub-pixel includes one light-emitting device, if one light-emitting device is regarded as a 1×1 dot pixel unit, then each sub-pixel is a 1×1 dot pixel unit, each pixel is a 1×3 linear pixel unit, and the plurality of pixels form an M×3N pixel matrix, where N is the number of pixels in the matrix arranged in a connection direction of multiple sub-pixels in a single pixel, and M is the number of pixels in the matrix arranged in a direction perpendicular to the connection direction of the multiple sub-pixels of the single pixel. The rectangular pixel array is adopted, so that light transmitting zones in the display region are evenly distributed, so that the light transmission uniformity of the light-emitting substrate 10 is improved.

With reference to FIG. 2, FIG. 10 and FIG. 11, the light-emitting device group 8 is disposed on a side of opaque connection traces away from the substrate 1, and the connection traces are, for example, a first signal line 22, a second signal line 42, and the like, so that a light transmitting area of the substrate 1 is increased, that is, a light transmittance of the light-emitting substrate 10 is increased, and the light transmittance greater than 70% may be achieved.

In some other embodiments, the light-emitting substrate 10 is applied to a backlight, and the display apparatus 100 is a liquid crystal display apparatus. In this case, the display apparatus 100 further includes a liquid crystal display panel, the light-emitting substrate 10 serves as a light source in a backlight module to provide the backlight for the display panel, and the display panel is configured to display an image to be displayed. The light-emitting device group 8 includes a plurality of light-emitting devices 81, the light-emitting devices 81 are light-emitting diodes, and the light-emitting diodes are mini light-emitting diodes or micro light-emitting diodes. The mini light-emitting diode or the micro light-emitting diode serves as the light-emitting device 81, so compared with the conventional LED, the mini LED or micro LED may have a smaller occupied volume and smaller particles. In a same screen size, a density of a light source per unit area is higher and a unit size of the light source is smaller, so that more precise local control may be realized on the light-emitting device 81, and the problem of non-uniform brightness of the light-emitting device 81 is avoided. That is, the light-emitting substrate 10 serves as the light source in the backlight module to provide the backlight for the display panel, so that the brightness of the backlight may be ensured to be uniform, and the display quality of the display apparatus 100 is ensured.

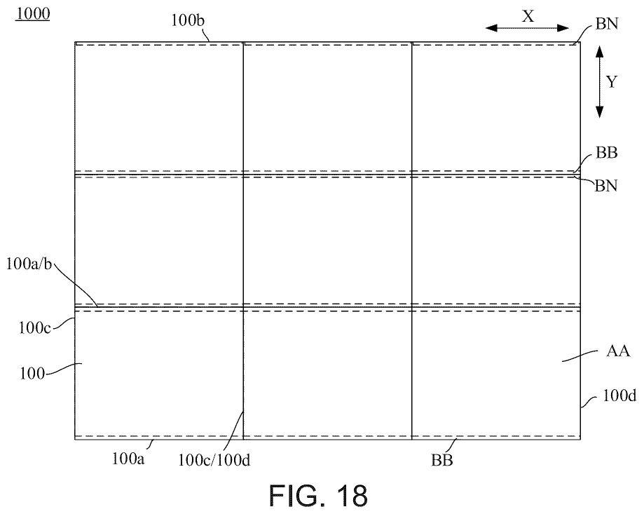

Some embodiments of the present disclosure provide a tiled display apparatus 1000, as shown in FIG. 18, which includes a plurality of display apparatuses 100 each according to any one of the above embodiments.

For example, as shown in FIG. 18, a cut-off region BN and a bonding region BB are disposed on two opposite sides of a display region AA. The tiled display apparatus 1000 is tiled and assembled by a plurality of display apparatuses 100, and the plurality of display apparatuses 100 in the tiled display apparatus 1000 are arranged in an array. A side surface of each display apparatus 100 proximate to a side on which a light-emitting substrate 10 included therein is provided with a bonding region BB is a first side surface 100a, and a side surface of each display apparatus 100 proximate to a side on which a light-emitting substrate 10 included therein is provided with a cut-off region BN is a second side surface 100b. In the tiled display apparatus 1000, first side surfaces 100a of two adjacent display apparatuses 100 are coplanar, and second side surfaces 100b of the two adjacent display apparatuses 100 are coplanar.

As shown in FIG. 18, each display apparatus 100 is, for example, a rectangle, a bonding region BB and a cut-off region BN of a light-emitting substrate 10 in each display apparatus 100 are located on two opposite sides of a display region AA of the display apparatus 100. Extension directions of the bonding region BB and the cut-off region BN are the first direction X, extension directions of the other two sides of the light-emitting substrate 10 that are not provided with the bonding region BB and the cut-off region BN are the second direction Y, so that the plurality of display apparatuses 100 form a matrix arranged in an array along the first direction X and the second direction Y.

In the display apparatus 100, the side surface proximate to the bonding region BB of the display substrate 10 included therein serves as the first side surface 100a, the side surface proximate to the cut-off region BN of the display substrate 10 included therein serves as the second side surface 100b, and the other two side surfaces proximate to the other two sides of the display substrate 10 included therein not provided with the bonding region BB and the cut-off region BN serve as a third side surface 100c and a fourth side surface 100d, respectively.

Further, of multiple display apparatuses 100 arranged in a row along the first direction X, first side surfaces 100a are coplanar, and second side surfaces 100b are also coplanar; and of two adjacent display apparatuses along the first direction X, a third side surface 100c of one display apparatus is connected to a fourth side surface 100d of the other display apparatus. Further, of multiple display apparatuses 100 arranged in a column along the second direction Y, third side surfaces 100c are coplanar, and fourth side surfaces 100d are also coplanar; and of two adjacent display apparatuses along the second direction Y, a first side surface 100a of one display apparatus is connected to a second side surface 100b of the other display apparatus.

As shown in FIG. 18, there is substantially no seam between two adjacent display apparatuses among multiple display apparatuses 100 arranged in a row along the first direction X, and there is only a seam at a tiled position between a side surface, proximate to a bonding region BB of a light-emitting substrate 10 included in one display apparatus 100 among the multiple display apparatuses 100, of the one display apparatuses 100 and a side surface, proximate to a cut-off region BN of a light-emitting substrate 10 included in another display apparatus 100, of the another display apparatuses 100. That is, there is a seam between two adjacent display apparatuses in multiple display apparatuses 100 arranged in a column along the second direction Y. That is to say, a size of a seam between adjacent display apparatuses among multiple display apparatuses 100 arranged in a row along the first direction X is less than a size of a seam between adjacent display apparatuses among multiple display apparatuses 100 arranged in a column along the second direction Y. However, since a size of the bonding region BB and a size of the cut-off region BN are small, a seam between two adjacent light-emitting substrates 10 is difficult to be found by naked eyes in a watching distance when the tiled display apparatus 1000 actually displays images, so that the display images of the tiled display apparatus 100 are complete, and a good display effect may be presented.

The above are only specific embodiments of the present disclosure, but the scope of protection of the present disclosure is not limited thereto, and any person skilled in the art may conceive of variations or replacements within the technical scope of the present disclosure, which shall fall within the protection scope of the present disclosure. Therefore, the protection scope of the present disclosure should be determined by the protection scope of the claims.

1. A light-emitting substrate, having a display region and a bonding region disposed on a side of the display region, the bonding region extending along a first direction; the light-emitting substrate comprising:
a substrate, wherein a first surface of the substrate includes a selected side edge, and the bonding region is proximate to the selected side edge;
a first metal layer, disposed on a side of the first surface of the substrate and including a plurality of first bonding electrodes, wherein the plurality of first bonding electrodes are spaced apart along the first direction, and portions of the plurality of first bonding electrodes proximate to the selected side edge are located in the bonding region;
a first insulating layer, disposed on a side of the first metal layer away from the substrate and including a plurality of via holes penetrating to the first metal layer, wherein a border of the first insulating layer proximate to the selected side edge is closer to the selected side edge than a border of the plurality of first bonding electrodes facing the selected side edge;
a second metal layer, disposed on a side of the first insulating layer away from the first metal layer and including a plurality of second bonding electrodes, wherein each second bonding electrode is connected to a corresponding first bonding electrode through a via hole; and
a conductive adhesive, located in the bonding region and covering portions of the plurality of second bonding electrodes proximate to the selected side edge;
wherein a ratio of a dimension of an edge portion of the first insulating layer in a second direction to a dimension of a first bonding electrode in the second direction is greater than or equal to one fifth (⅕) and less than or equal to a half (½), the edge portion of the first insulating layer is a portion, located between the border of the plurality of first bonding electrodes facing the selected side edge and the selected side edge, of the first insulating layer, and the second direction is perpendicular to the first direction.

2. The light-emitting substrate according to claim 1, wherein a distance between the border of the first insulating layer proximate to the selected side edge and the selected side edge is less than a distance between an end of the conductive adhesive proximate to the selected side edge and the selected side edge; or
the distance between the border of the first insulating layer proximate to the selected side edge and the selected side edge is less than the distance between the end of the conductive adhesive proximate to the selected side edge and the selected side edge, and the ratio of the dimension of the edge portion of the first insulating layer in the second direction to the dimension of the first bonding electrode in the second direction is greater than or equal to one third (⅓) and less than or equal to a half (½).

3. (canceled)

4. The light-emitting substrate according to claim 1, further comprising:
an insulating barrier layer, disposed on a side of the second metal layer away from the substrate and including an edge portion located in the bonding region, wherein the edge portion of the insulating barrier layer is at least disposed on a side of the edge portion of the first insulating layer away from the substrate; and a border of the insulating barrier layer proximate to the selected side edge is closer to the selected side edge than the border of the first insulating layer proximate to the selected side edge.

5. The light-emitting substrate according to claim 4, wherein the light-emitting substrate has the display region and a peripheral region outside the display region, and the peripheral region includes the bonding region; the plurality of first bonding electrodes and the plurality of second bonding electrodes are located in the peripheral region;
the light-emitting substrate further comprises:
a first passivation layer, disposed on a side of the second metal layer away from the substrate and including an edge portion located in the bonding region, wherein the edge portion of the first passivation layer serves as the edge portion of the insulating barrier layer; or
wherein the light-emitting substrate has the display region and a peripheral region outside the display region, and the peripheral region includes the bonding region; the plurality of first bonding electrodes and the plurality of second bonding electrodes are located in the peripheral region;
the light-emitting substrate further comprises:
a first passivation layer, disposed on a side of the second metal layer away from the substrate and including a first portion located in the peripheral region, wherein the first portion of the first passivation layer is disposed on a side, away from the substrate, of the portions of the plurality of second bonding electrodes proximate to the display region; and
a second insulating layer, disposed on a side of the first passivation layer away from the substrate and including an edge portion located in the bonding region, wherein the edge portion of the second insulating layer serves as the edge portion of the insulating barrier layer.

6-7. (canceled)

8. The light-emitting substrate according to claim 1, wherein
the second metal layer further includes a residual metal located in the bonding region, wherein the residual metal is located at the border of the first insulating layer proximate to the selected side edge, and the residual metal extends along the first direction; and
the conductive adhesive is electrically insulated from the residual metal.

9. The light-emitting substrate according to claim 1, wherein
the display region includes display unit regions, and a display unit region includes a light-emitting zone and a driving zone; the first metal layer further includes a plurality of first signal lines located in the display region, at least one first signal line passes through the light-emitting zone, and the plurality of first signal lines do not pass through the driving zone;
the light-emitting substrate further comprises:
light-emitting device groups, located on a side of the second metal layer away from the substrate, wherein a light-emitting device group is disposed in the light-emitting zone and electrically connected to the second metal layer, and an orthographic projection of the light-emitting device group on the substrate is within an orthographic projection of a portion of the at least one first signal line passing through the light-emitting zone on the substrate;
driving chips, located on the side of the second metal layer away from the substrate, wherein a driving chip is disposed in the driving zone and electrically connected to the second metal layer, and the driving chip is electrically connected to the light-emitting device group; and
at least one prop structure, wherein a prop structure is disposed in the driving zone and located between the driving chip and the substrate, and the prop structure is configured to increase a distance between the driving chip and the substrate.

10. The light-emitting substrate according to claim 9, wherein the first metal layer further includes: pads, wherein a pad is located in the driving zone and serves as the prop structure, and the pad is electrically insulated from the plurality of first signal lines and electrically insulated from the second metal layer; and
an orthographic projection of the driving chip on the substrate is within an orthographic projection of the pad on the substrate.

11. The light-emitting substrate according to claim 9, further comprising a third insulating layer, wherein the third insulating layer includes at least one insulating structure, an insulating structure is located in the driving zone and serves as the prop structure, and an orthographic projection of the driving chip on the substrate is within an orthographic projection of the insulating structure on the substrate.

12. The light-emitting substrate according to claim 11, wherein the third insulating layer is located between the first insulating layer and the second metal layer; or the third insulating layer is located between the substrate and the first insulating layer.

13. The light-emitting substrate according to claim 1, wherein the light-emitting substrate has the display region and a peripheral region outside the display region, the peripheral region includes a cut-off region and the bonding region, and the cut-off region and the bonding region are located at different sides of the display region;
the light-emitting substrate further comprises:
a plurality of test connection lines, located in the first metal layer, wherein ends of the plurality of test connection lines are located in the display region, and other ends of the plurality of test connection lines extend to the cut-off region and are flush with a border of the cut-off region away from the display region.

14. The light-emitting substrate according to claim 1, wherein the light-emitting substrate has the display region and a peripheral region outside the display region, the peripheral region includes a cut-off region and the bonding region, and the cut-off region and the bonding region are located at different sides of the display region; and
the light-emitting substrate further comprises:
a plurality of test connection lines and a protection structure, wherein the plurality of test connection lines are located in the second metal layer, ends of the plurality of test connection lines are located in the display region, other ends of the plurality of test connection lines extend to the cut-off region and are flush with a border of the cut-off region away from the display region; and the protection structure is configured to prevent the plurality of test connection lines from being short-connected.

15. The light-emitting substrate according to claim 14, wherein the first insulating layer extends to the cut-off region, a border of the first insulating layer proximate to the cut-off region is flush with the border of the cut-off region away from the display region, and a portion of the first insulating layer extending to the cut-off region serves as the protection structure; or
the first insulating layer does not extend to the cut-off region;
the light-emitting substrate further comprises:
a plurality of isolation retaining walls, located in the cut-off region, wherein the plurality of isolation retaining walls are made of an insulating material; and each isolation retaining wall is disposed between two adjacent test connection lines, and the isolation retaining walls serve as the protection structure.

16. (canceled)

17. A light-emitting substrate, having a display region, the display region including display unit regions, a display unit region including a light-emitting zone and a driving zone;
the light-emitting substrate comprising:
a substrate;
a first metal layer, disposed on a side of a first surface of the substrate and including a plurality of first signal lines located in the display region, wherein at least one first signal line passes through the light-emitting zone, and the plurality of first signal lines do not pass through the driving zone;
a first insulating layer, disposed on a side of the first metal layer away from the substrate;
a second metal layer, disposed on a side of the first insulating layer away from the first metal layer and including a plurality of second signal lines located in the display region;
light-emitting device groups, disposed on a side of the second metal layer away from the substrate, wherein a light-emitting device group is located in the light-emitting zone and electrically connected to the second metal layer, and an orthographic projection of the light-emitting device group on the substrate is within an orthographic projection of a portion of the at least one first signal line passing through the light-emitting zone on the substrate;
driving chips, disposed on the side of the second metal layer away from the substrate, wherein a driving chip is located in the driving zone and electrically connected to the second metal layer, and the driving chip is electrically connected to the light-emitting device group; and
prop structures, wherein a prop structure is disposed between the driving chip and the substrate and located in the driving zone, and the prop structure is configured to increase a distance between the driving chip and the substrate.

18. The light-emitting substrate according to claim 17, wherein the light-emitting device group includes a plurality of light-emitting devices, and the light-emitting devices are mini light-emitting diodes or micro light-emitting diodes.

19. A light-emitting substrate, having a display region and a peripheral region outside the display region, the peripheral region including a cut-off region;
the light-emitting substrate comprising:
a substrate;
a first metal layer, disposed on a side of a first surface of the substrate;
a first insulating layer, disposed on a side of the first metal layer away from the substrate;
a second metal layer, disposed on a side of the first insulating layer away from the first metal layer and including a plurality of test connection lines, wherein ends of the plurality of test connection lines are located in the display region, and other ends of the plurality of test connection lines extends to the cut-off region and are flush with a border of the cut-off region away from the display region; and
a protection structure, configured to prevent the plurality of test connection lines from being short-connected.

20. A display apparatus, comprising the light-emitting substrate according to claim 1.

21. A tiled display apparatus, comprising a plurality of display apparatuses each according to claim 20.

22. The tiled display apparatus according to claim 21, wherein the plurality of display apparatuses are arranged in an array along a first direction and a second direction;
a light-emitting substrate included in each display apparatus has a display region and a peripheral region outside the display region, the peripheral region includes a cut-off region and a bonding region, and the cut-off region and the bonding region are located at different sides of the display region;
a side surface of each display apparatus proximate to a side on which the light-emitting substrate included therein is provided with the bonding region is a first side surface, a side surface of each display apparatus proximate to a side on which the light-emitting substrate included therein is provided with the cut-off region is a second side surface, and the bonding region and the cut-off region of the light-emitting substrate extend along the first direction;
first side surfaces of two adjacent display apparatuses are coplanar, and second side surfaces of the two adjacent display apparatuses are coplanar; and
a size of a seam between two adjacent display apparatuses among multiple display apparatuses arranged in a row along the first direction is less than a size of a seam between two adjacent display apparatuses among multiple display apparatuses arranged in a column along the second direction.

23. A display apparatus, comprising the light-emitting substrate according to claim 17.

24. A display apparatus, comprising the light-emitting substrate according to claim 19.
